(19) United States
(12) Patent Application Publication
(10) Pub. No.: US 2025/0175158 A1
(43) Pub. Date: May 29, 2025

(54) MULTIPLEXER

(71) Applicant: Murata Manufacturing Co., Ltd., Nagaokakyo-shi (JP)

(72) Inventor: Motoki OZASA, Nagaokakyo-shi (JP)

(21) Appl. No.: 18/945,923

(22) Filed: Nov. 13, 2024

(30) Foreign Application Priority Data
Nov. 27, 2023 (JP) 2023-200176

(51) Int. Cl. H03H 9/60; H03H 9/13; H03H 9/70

(52) U.S. Cl. CPC H03H 9/605; H03H 9/133; H03H 9/70

(57) ABSTRACT

A multiplexer includes first and second filters respectively with a first pass band and a second pass band on a higher frequency side than the first pass band. The first filter includes series-arm resonators and parallel-arm resonators, a resonance band width of at least one of the series-arm resonators is wider than the first pass band, one of the series-arm resonators is coupled closest to a common terminal among the series-arm resonators and the parallel-arm resonators. An anti-resonant frequency of the one of the series-arm resonators is lower than a high frequency end of the second pass band and is lowest among anti-resonant frequencies of the series-arm resonators.

### CROSS REFERENCE TO RELATED APPLICATIONS

This application claims the benefit of priority to Japanese Patent Application No. 2023-200176 filed on Nov. 27, 2023. The entire contents of this application are hereby incorporated herein by reference.

### BACKGROUND OF THE INVENTION

### 1. Field of the Invention

The present invention relates to multiplexers each including an acoustic wave filter.

### 2. Description of the Related Art

International Publication No. 2019/188007 discloses a multiplexer in which a first filter and a second filter each including an acoustic wave resonator are coupled to a common terminal. Specifically, the multiplexer is formed using an acoustic wave resonator having a wider resonance band width (for example, 45 MHZ) relative to band widths of two filters (for example, 35 MHZ+α) and an inter-passband gap of the two filters (for example, 10 MHz or less).

However, when the first filter is configured using an acoustic wave resonator having a wider resonance band width relative to a pass band width and the inter-passband gap, impedance in the pass band of the second filter is affected by the impedance of the acoustic wave resonator and easily deviates from a reference impedance. This may cause an increase of insertion loss of the multiplexer.

### SUMMARY OF THE INVENTION

Example embodiments of the present invention provide multiplexers in each of which insertion loss in pass bands of filters coupled in common is reduced.

A multiplexer according to an example embodiment of the present invention includes a first filter with a first pass band and a second filter with a second pass band on a higher frequency side than the first pass band. The first filter and the second filter are coupled to a common terminal, the first filter includes two or more series-arm resonators each including an acoustic wave resonator and provided in a series-arm path coupling an input end and an output end, and one or more parallel-arm resonators each including an acoustic wave resonator and coupled between the series-arm path and a ground, a resonance band width of at least one of the two or more series-arm resonators included in the first filter is wider than the first pass band, a first series-arm resonator among the two or more series-arm resonators included in the first filter is coupled closest to the common terminal among the two or more series-arm resonators and the one or more parallel-arm resonators included in the first filter, and an anti-resonant frequency of the first series-arm resonator is lower than a high frequency end of the second pass band, and is lowest among anti-resonant frequencies positioned on the higher frequency side than the first pass band among anti-resonant frequencies of the two or more series-arm resonators included in the first filter.

A multiplexer according to an example embodiment of the present invention includes a first filter with a first pass band and a second filter with a second pass band on a higher frequency side than the first pass band. The first filter and the second filter are coupled to a common terminal, the second filter includes two or more series-arm resonators each including an acoustic wave resonator and provided in a series-arm path coupling an input end and an output end, and one or more parallel-arm resonators each including an acoustic wave resonator and coupled between the series-arm path and a ground, a resonance band width of at least one of the two or more series-arm resonators included in the second filter is wider than the second pass band, a second series-arm resonator among the two or more series-arm resonators included in the second filter is coupled closest to the common terminal among the two or more series-arm resonators and the one or more parallel-arm resonators included in the second filter, and a resonant frequency of the second series-arm resonator is higher than a high frequency end of the first pass band, and is highest among resonant frequencies positioned on the higher frequency side than the first pass band among resonant frequencies of the two or more series-arm resonators included in the second filter.

A multiplexer according to an example embodiment of the present invention includes a first filter with a first pass band and a second filter with a second pass band on a higher frequency side than the first pass band. The first filter and the second filter are coupled to a common terminal, the first filter includes two or more series-arm resonators each including an acoustic wave resonator and provided in a series-arm path coupling an input end and an output end, and one or more parallel-arm resonators each including an acoustic wave resonator and coupled between the series-arm path and a ground, the second filter includes two or more series-arm resonators each including an acoustic wave resonator and provided in a series-arm path coupling an input end and an output end, and one or more parallel-arm resonators each including an acoustic wave resonator and coupled between the series-arm path and the ground, each of the acoustic wave resonators of the first filter and the second filter includes an interdigital transducer (IDT) electrode, an electrode finger pitch of the IDT electrode of at least one of the two or more series-arm resonators included in the first filter is smaller than an electrode finger pitch of the IDT electrode of at least one of the one or more parallel-arm resonators included in the second filter, a first series-arm resonator among the two or more series-arm resonators included in the first filter is coupled closest to the common terminal among the two or more series-arm resonators and the one or more parallel-arm resonators included in the first filter, and an anti-resonant frequency of the first series-arm resonator is lower than a high frequency end of the second pass band and is lowest among anti-resonant frequencies positioned on the higher frequency side than the first pass band among anti-resonant frequencies of the two or more series-arm resonators included in the first filter.

A multiplexer according to an example embodiment of the present invention includes a first filter with a first pass band and a second filter with a second pass band on a higher frequency side than the first pass band. The first filter and the second filter are coupled to a common terminal, the first filter includes two or more series-arm resonators each including an acoustic wave resonator and provided in a series-arm path coupling an input end and an output end, and one or more parallel-arm resonators each including an acoustic wave resonator and coupled between the series-arm path and a ground, the second filter includes two or more series-arm resonators each including an acoustic wave resonator and provided in a series-arm path coupling an input end and an output end, and one or more parallel-arm resonators each including an acoustic wave resonator and coupled between the series-arm path and the ground, each of the acoustic wave resonators of the first filter and the second filter includes an IDT electrode, an electrode finger pitch of the IDT electrode of at least one of the two or more series-arm resonators included in the second filter is smaller than an electrode finger pitch of the IDT electrode of at least one of the one or more parallel-arm resonators included in the second filter, a second series-arm resonator among the two or more series-arm resonators included in the second filter is coupled closest to the common terminal among the two or more series-arm resonators and the one or more parallel-arm resonators included in the second filter, and an electrode finger pitch of the IDT electrode of the second series-arm resonator is smallest among electrode finger pitches of the IDT electrodes of the two or more series-arm resonators included in the second filter.

According to example embodiments of the present invention, it is possible to provide multiplexers in each of which insertion loss in pass bands of filters coupled in common is reduced.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit configuration diagram of multiplexer according to an example embodiment of the present invention.

FIG. 2A is a plan view and sectional views schematically illustrating a first example of an acoustic wave resonator of a multiplexer according to an example embodiment of the present invention.

FIG. 2B is a sectional view schematically illustrating a second example of an acoustic wave resonator of a multiplexer according to an example embodiment of the present invention.

FIG. 2C is a sectional view schematically illustrating a third example of an acoustic wave resonator of a multiplexer according to an example embodiment of the present invention.

FIG. 3 is a graph illustrating a bandpass characteristic of a multiplexer according to an example embodiment of the present invention and an impedance characteristic of each of series-arm resonators of a first filter.

FIG. 4A is a graph illustrating a bandpass characteristic of a second filter in a multiplexer according to each of an example embodiment of the present invention and a comparative example.

FIG. 4B is an immittance chart illustrating impedance in a second pass band of a multiplexer according to each of an example embodiment of the present invention and the comparative example when viewed from a common terminal.

FIG. 5 is a graph illustrating an impedance characteristic and a susceptance characteristic of a first series-arm resonator according to each of an example embodiment of the present invention and the comparative example.

FIG. 6A is a schematic plan view illustrating a configuration of an IDT electrode including a floating withdrawal electrode.

FIG. 6B is a schematic plan view illustrating a configuration of an IDT electrode including a polarity-inverted withdrawal electrode.

FIG. 6C is a schematic plan view illustrating a configuration of an IDT electrode including a filled-in withdrawal electrode.

FIG. 7 is a graph illustrating a bandpass characteristic of a multiplexer according to an example embodiment of the present invention and an impedance characteristic of each of series-arm resonators of a second filter.

FIG. 8A is a graph illustrating a bandpass characteristic of a first filter in a multiplexer according to each of an example embodiment of the present invention and the comparative example.

FIG. 8B is an immittance chart illustrating impedance in a first pass band of the multiplexer according to each of an example embodiment of the present invention and the comparative example when viewed from the common terminal.

FIG. 9 is a graph illustrating an impedance characteristic and a susceptance characteristic of a second series-arm resonator according to each of an example embodiment of the present invention and the comparative example.

FIG. 10 is a graph illustrating a bandpass characteristic of a multiplexer according to an example embodiment of the present invention and an impedance characteristic of each of parallel-arm resonators of a second filter.

### DETAILED DESCRIPTION OF THE EXAMPLE EMBODIMENTS

Hereinafter, example embodiments of the present disclosure will be described in detail with reference to the drawings. The example embodiments described below are all comprehensive or specific examples. Numerical values, shapes, materials, elements, the arrangement and coupling manner of the elements, and the like illustrated in the following example embodiments are merely examples, and are not intended to limit the scope or spirit of the present invention. Among the elements in the following example embodiments, an element not recited in an independent claim is described as an optional element. Further, sizes or size ratios of the elements illustrated in the drawings are not necessarily precise.

Each drawing is a schematic view in which emphasis, omission, or adjustment of a ratio is provided as appropriate in order to illustrate the present invention, and is not necessarily illustrated precisely. Thus, shapes, positional relationships, and ratios may be different from actual ones. In each drawing, the same or substantially the same components are denoted by the same reference signs, and redundant description may be omitted or simplified.

In the circuit configuration of the present disclosure, the term “coupled” includes not only a case of being directly coupled by a coupling terminal and/or a wiring conductor but also a case of being electrically coupled via a matching element such as an inductor or a capacitor and a switch circuit. The term “coupled between A and B” means being coupled to both A and B between A and B.

Further, terms indicating relationships between elements such as “parallel” and “perpendicular”, a term indicating a shape of an element such as “rectangular”, and a numerical range each do not indicate only a strict meaning, but indicate an equivalent or substantially equivalent range which includes an error of several percent, for example.

In the following example embodiments, for example, a pass band of a filter is defined as a frequency band between two frequencies that are larger by about 3 dB than the minimum value of the insertion loss in the pass band.

In an example embodiment of the present invention, a resonance band width means a frequency difference between an anti-resonant frequency and a resonant frequency of an acoustic wave resonator.

In the present disclosure, Band A means a frequency band defined in advance by a standardization organization (for example, 3GPP (registered trademark), Institute of Electrical and Electronics Engineers (IEEE), or the like) for a communication system constructed using Radio Access Technology (RAT). In the present example embodiment, as the communication system, for example, Long Term Evolution (LTE) system, 5th Generation (5G)-New Radio (NR) system, Wireless Local Area Network (WLAN) system, and the like may be used, but the communication system is not limited thereto.

An uplink operating band of Band A means a frequency range designated for uplink in Band A. A downlink operating band of Band A means a frequency range designated for downlink in Band A.

### Example Embodiments

### 1. Circuit Configuration of Multiplexer 1

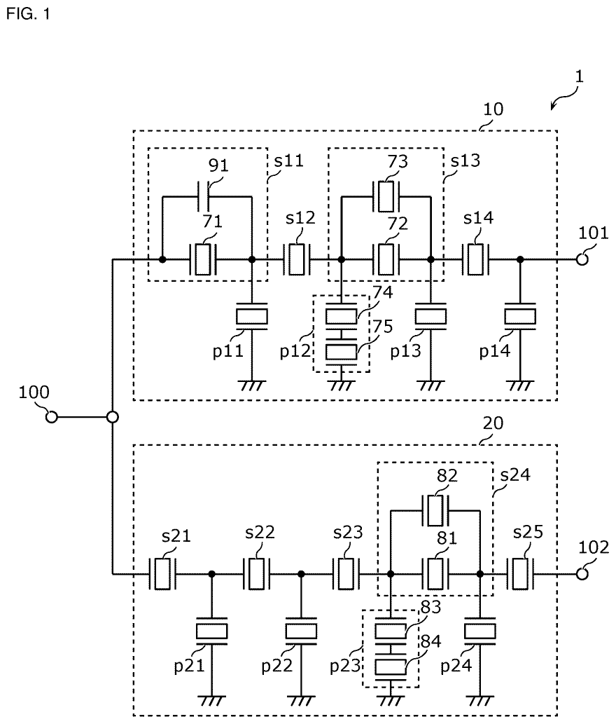

FIG. 1 is a circuit configuration diagram of a multiplexer 1 according to an example embodiment of the present invention. As illustrated in FIG. 1, the multiplexer 1 includes filters 10 and 20, a common terminal 100, an input terminal 101, and an output terminal 102.

The common terminal 100 is coupled to an antenna, for example.

The filter 10 is an example of a first filter and has a first pass band including the uplink operating band of Band A. An output end of the filter 10 is coupled to the common terminal 100, and an input end of the filter 10 is coupled to the input terminal 101. The filter 10 includes a plurality of acoustic wave resonators.

The filter 20 is an example of a second filter and has a second pass band including the downlink operating band of Band A. An input end of the filter 20 is coupled to the common terminal 100, and an output end of the filter 20 is coupled to the output terminal 102. That is, the filters 10 and 20 are coupled in common. The filter 20 includes a plurality of acoustic wave resonators. In the present example embodiment, the second pass band of the filter 20 is positioned on a higher frequency side than the first pass band of the filter 10.

Band 30 of LTE (uplink operating band: about 2305-about 2315 MHz, downlink operating band: about 2350-about 2360 MHz) is applied to Band A, for example.

The second pass band of the filter 20 is positioned on a higher frequency side than the first pass band of the filter 10, and the pass bands of the filters 10 and 20 are not necessarily pass bands including the uplink operating band and the downlink operating band in the same Band. For example, it is acceptable that the second pass band of the filter 20 includes Band B, and the first pass band of the filter 10 includes Band C on a lower frequency side than Band B.

In the multiplexer 1 according to the present example embodiment, a filter other than the filters 10 and 20 may be coupled to the common terminal 100. An impedance matching circuit including at least one of an inductor and a capacitor may be coupled to either a path coupling the common terminal 100 and the input terminal 101 or a path coupling the common terminal 100 and the output terminal 102.

The multiplexer 1 does not necessarily include the common terminal 100, the input terminal 101, and the output terminal 102.

### 2. Circuit Configuration of Filters 10 and 20

Next, the circuit configuration of the filters 10 and 20 of the multiplexer 1 will be exemplified.

As illustrated in FIG. 1, the filter 10 includes series-arm resonators s11, s12, s13, and s14 and parallel-arm resonators p11, p12, p13, and p14.

The series-arm resonators s11 to s14 are disposed on a series-arm path coupling the output end and the input end of the filter 10 (coupling common terminal 100 and input terminal 101). The parallel-arm resonators p11 to p14 are each coupled between a ground and a node (point on series-arm path) of each of the series-arm resonators s11 to s14 and the input terminal 101. With the above-described coupling configuration, the filter 10 is, for example, a ladder band pass filter.

The series-arm resonator s11 is an example of a first series-arm resonator, and is coupled closest to the common terminal 100 among the series-arm resonators s11 to s14 and the parallel-arm resonators p11 to p14 included in the filter 10. The series-arm resonator s11 includes an acoustic wave resonator 71 (first acoustic wave resonator) and a capacitor 91 (first capacitance element) coupled to the acoustic wave resonator 71 in parallel. The capacitor 91 is an example of bridging capacitance, and does not shift a resonant frequency frs11 of the series-arm resonator s11 from a resonant frequency fr71 of the acoustic wave resonator 71, but shifts an anti-resonant frequency fas11 of the series-arm resonator s11 to a lower frequency side than an anti-resonant frequency fa71 of the acoustic wave resonator 71. That is, with the capacitor 91 being coupled to the acoustic wave resonator 71 in parallel, a resonance band width of the series-arm resonator s11 becomes narrower relative to a resonance band width (anti-resonant frequency minus resonant frequency) of the acoustic wave resonator 71.

In the present example embodiment, each of a series-arm resonator and a parallel-arm resonator is defined to include an acoustic wave resonator and a means to adjust a resonance band width of the acoustic wave resonator. For example, each of the series-arm resonator and the parallel-arm resonator includes an acoustic wave resonator and a capacitance element (bridging capacitance) coupled to the acoustic wave resonator in parallel. The means to adjust the resonance band width includes, in addition to the bridging capacitance, adjusting a film thickness of a dielectric film added to an IDT electrode of the acoustic wave resonator, and withdrawal processing of the IDT electrode of the acoustic wave resonator.

The series-arm resonator s12 includes an acoustic wave resonator and is coupled between the series-arm resonator s11 and the series-arm resonator s13. The series-arm resonator s13 includes acoustic wave resonators 72 and 73 coupled in parallel, and is coupled between the series-arm resonator s12 and the series-arm resonator s14. The series-arm resonator s14 includes an acoustic wave resonator and is coupled between the series-arm resonator s13 and the input terminal 101.

The parallel-arm resonator p11 includes an acoustic wave resonator and is coupled between the ground and a node of the series-arm resonators s11 and s12. The parallel-arm resonator p12 includes acoustic wave resonators 74 and 75 coupled in series, and is coupled between the ground and a node of the series-arm resonators s12 and s13. The parallel-arm resonator p13 includes an acoustic wave resonator and is coupled between the ground and a node of the series-arm resonators s13 and s14. The parallel-arm resonator p14 includes an acoustic wave resonator and is coupled between the ground and the node of the series-arm resonator s14 and the input terminal 101.

It is sufficient that the filter 10 includes, for example, two or more series-arm resonators including the series-arm resonator s11 and one or more parallel-arm resonators including the parallel-arm resonator p11. When the filter 20 includes two or more series-arm resonators including the series-arm resonator s21 and one or more parallel-arm resonators, the filter 10 need not include an acoustic wave resonator and may be an LC filter constituted of an inductor and a capacitor, for example.

As illustrated in FIG. 1, the filter 20 includes series-

arm resonators s21, s22, s23, s24, and s25 and parallel-arm resonators p21, p22, p23, and p24.

The series-arm resonators s21 to s25 are disposed on a series-arm path coupling an input end and an output end of the filter 20 (coupling common terminal 100 and output terminal 102). The parallel-arm resonators p21 to p24 are each coupled between the ground and a node (point on series-arm path) of each of the series-arm resonators s21 to s25 and the output terminal 102. With the above-described coupling configuration, the filter 20 constitutes a ladder band pass filter.

The series-arm resonator s21 is an example of a second series-arm resonator, includes an acoustic wave resonator, and is coupled closest to the common terminal 100 among the series-arm resonators s21 to s25 and the parallel-arm resonators p21 to p24 included in the filter 20.

The series-arm resonator s22 includes an acoustic wave resonator and is coupled between the series-arm resonator s21 and the series-arm resonator s23. The series-arm resonator s23 includes an acoustic wave resonator and is coupled between the series-arm resonator s22 and the series-arm resonator s24. The series-arm resonator s24 includes acoustic wave resonators 81 and 82 coupled in parallel, and is coupled between the series-arm resonator s23 and the series-arm resonator s25. The series-arm resonator s25 includes an acoustic wave resonator and is coupled between the series-arm resonator s24 and the output terminal 102.

The parallel-arm resonator p21 is an example of a first parallel-arm resonator, includes an acoustic wave resonator, and is coupled between the ground and a node of the series-arm resonators s21 and s22. The parallel-arm resonator p22 includes an acoustic wave resonator and is coupled between the ground and a node of the series-arm resonators s22 and s23. The parallel-arm resonator p23 includes acoustic wave resonators 83 and 84 coupled in series, and is coupled between the ground and a node of the series-arm resonators s23 and s24. The parallel-arm resonator p24 includes an acoustic wave resonator and is coupled between the ground and a node of the series-arm resonators s24 and s25.

It is sufficient that the filter 20 includes two or more series-arm resonators including the series-arm resonator s21 and one or more parallel-arm resonators. When the filter 10 includes two or more series-arm resonators including the series-arm resonator s11 and one or more parallel-arm resonators including the parallel-arm resonator p11, the filter 20 need not include an acoustic wave resonator and may be an LC filter including an inductor and a capacitor, for example.

### 3. Structure of Acoustic Wave Resonator

Next, a structure of the acoustic wave resonator included in the filters 10 and 20 of the multiplexer 1 will be described.

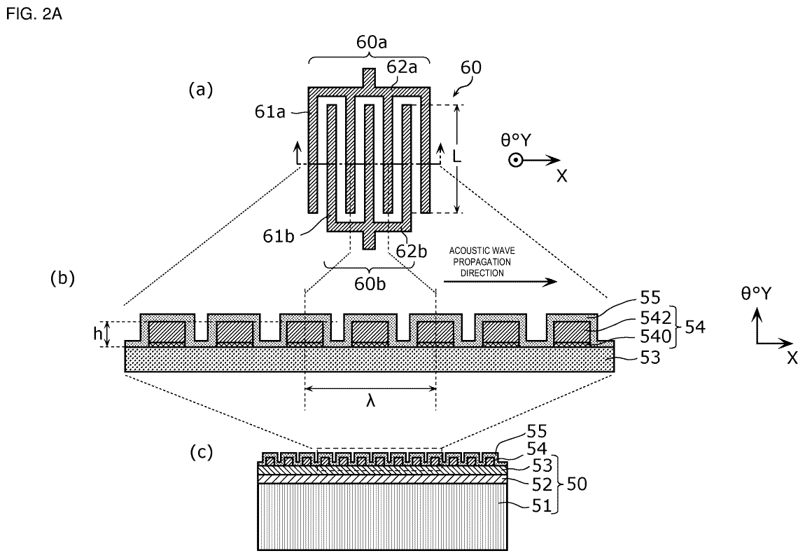

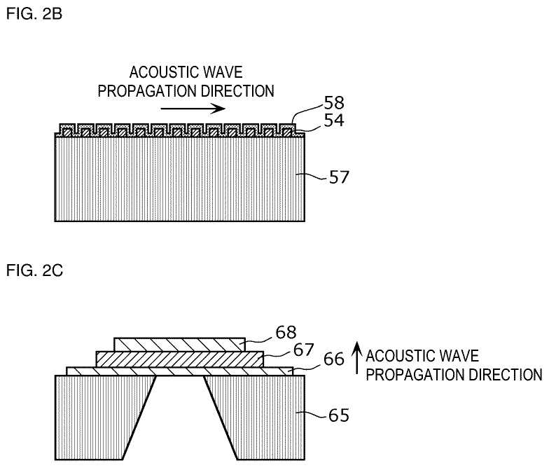

FIG. 2A is a plan view and sectional views schematically illustrating a first example of an acoustic wave resonator of the multiplexer 1 according to the example embodiment. FIG. 2A illustrates a basic structure of each of the plurality of acoustic wave resonators of the filters 10 and 20. An acoustic wave resonator 60 illustrated in FIG. 2A is provided to describe a typical structure of the acoustic wave resonator of the filters 10 and 20, and the number, length, and the like of electrode fingers of an electrode are not limited to those of the electrode fingers of the electrode in the acoustic wave resonator 60.

The acoustic wave resonator 60 includes a piezoelectric substrate 50 and comb-shaped electrodes 60a and 60b.

As illustrated in (a) of FIG. 2A, a pair of the comb-shaped electrodes 60a and 60b facing each other is provided on the piezoelectric substrate 50. The comb-shaped electrode 60a includes a plurality of electrode fingers 61a parallel to each other and a busbar electrode 62a coupling the plurality of electrode fingers 61a. The comb-shaped electrode 60b includes a plurality of electrode fingers 61b parallel to each other and a busbar electrode 62b coupling the plurality of electrode fingers 61b. The plurality of electrode fingers 61a and 61b are provided in a direction orthogonal to an acoustic wave propagation direction (X-axis direction).

An IDT electrode 54 includes the plurality of electrode fingers 61a and 61b and the busbar electrodes 62a and 62b has a multilayer structure including an adhesion layer 540 and a main electrode layer 542, as illustrated in (b) of FIG. 2A.

The adhesion layer 540 is a layer to improve an adhesion property between the piezoelectric substrate 50 and the main electrode layer 542, and Ti is used as a material thereof, for example. The main electrode layer 542 uses, for example, Al including 1% of Cu as a material. A protection layer 55 covers the comb-shaped electrodes 60a and 60b. The protection layer 55 is a layer to protect the main electrode layer 542 from the external environment, to adjust frequency-temperature characteristics, and to improve moisture resistance, and is a dielectric film including silicon dioxide as a main component, for example.

The material of each of the adhesion layer 540, the main electrode layer 542, and the protection layer 55 is not limited to the above-described material. Further, the IDT electrode 54 may have a structure other than the above-described multilayer structure. The IDT electrode 54 may be made of, for example, a metal such as Ti, Al, Cu, Pt, Au, Ag, or Pd, or an alloy thereof, or may be made of a plurality of multilayer bodies constituted of the above-described metal or alloy. The protection layer 55 is not necessarily formed.

Next, the multilayer structure of the piezoelectric substrate 50 will be described.

As illustrated in (c) of FIG. 2A, the piezoelectric substrate 50 includes a high acoustic velocity support substrate 51, a low acoustic velocity film 52, and a piezoelectric film 53, and has a structure in which the high acoustic velocity support substrate 51, the low acoustic velocity film 52, and the piezoelectric film 53 are laminated in this order.

The piezoelectric film 53 is made of, for example, a θ° Y-cut X-propagation LiTaO₃ piezoelectric single crystal or piezoelectric ceramics (a lithium tantalate single crystal cut along a plane with an axis as a normal line, the axis which is rotated by θ° from a Y-axis with the X-axis being a center axis, or ceramics; that is the single crystal or the ceramics in which a surface acoustic wave propagates in the X-axis direction). The material of the piezoelectric single crystal used as the piezoelectric film 53 and the cut-angle θ are each appropriately selected in accordance with required specifications for each filter.

The high acoustic velocity support substrate 51 is a substrate that supports the low acoustic velocity film 52, the piezoelectric film 53, and the IDT electrode 54. The high acoustic velocity support substrate 51 is a substrate in which the acoustic velocity of a bulk wave in the high acoustic velocity support substrate 51 is higher than that of an acoustic wave such as a surface wave and a boundary wave propagating through the piezoelectric film 53, and confines the surface acoustic wave in a portion where the piezoelectric film 53 and the low acoustic velocity film 52 are laminated and prevents the surface acoustic wave from leaking to a portion lower than the high acoustic velocity support substrate 51. The material of the high acoustic velocity support substrate 51 may be, for example, a piezoelectric body such as aluminum nitride, lithium tantalate, lithium niobate, or quartz; a ceramic material such as alumina, sapphire, magnesia, silicon nitride, silicon carbide, zirconia, cordierite, mullite, steatite, forsterite, spinel, or sialon; a dielectric such as aluminum oxide, silicon oxynitride, diamond-like carbon (DLC), or diamond; a semiconductor such as silicon; or a material including any of the above materials as a main component. The spinel includes, for example, an aluminum compound including oxygen and one or more elements selected from Mg, Fe, Zn, Mn, and the like. Examples of the spinel include MgAl₂O₄, FeAl₂O₄, ZnAl₂O₄, and MnAl₂O₄.

The low acoustic velocity film 52 is a film in which an acoustic velocity of a bulk wave in the low acoustic velocity film 52 is lower than that of a bulk wave propagating through the piezoelectric film 53, and is disposed between the piezoelectric film 53 and the high acoustic velocity support substrate 51. With the above structure and the property of an acoustic wave that energy is essentially concentrated in a medium having a low acoustic velocity, leakage of the energy of the surface acoustic wave to the outside of the piezoelectric film 53 is suppressed. The material of the low acoustic velocity film 52 may be, for example, a dielectric such as glass, silicon oxide, silicon oxynitride, lithium oxide, tantalum oxide, or a compound obtained by adding fluorine, carbon, or boron to silicon oxide; or a material including any of the above materials as a main component.

With the use of the multilayer structure of the piezoelectric substrate 50, a Q factor at a resonant frequency and an anti-resonant frequency may be made significantly higher as compared with a structure of the related art in which a piezoelectric substrate is used as a single layer. That is, since an acoustic wave resonator having a high Q factor may be constituted, a filter having low insertion loss may be provided using the acoustic wave resonator.

The high acoustic velocity support substrate 51 may have a structure in which a support substrate and a high acoustic velocity film, in which an acoustic velocity of a bulk wave propagating therethrough is higher than that of an acoustic wave such as a surface wave or a boundary wave propagating through the piezoelectric film 53, are laminated. In the case above, the material of the high acoustic velocity film may be the same material as the material of the high acoustic velocity support substrate 51. The material of the support substrate may be, for example, a piezoelectric body such as aluminum nitride, lithium tantalate, lithium niobate, or quartz; a ceramic material such as alumina, sapphire, magnesia, silicon nitride, silicon carbide, zirconia, cordierite, mullite, steatite, or forsterite; a dielectric such as diamond or glass; a semiconductor such as silicon or gallium nitride; a resin; or a material including any of the above materials as a main component.

In the present description, the “main component of a material” refers to a component whose proportion in the material exceeds 50% by weight. The main component may be provided in any state of a single crystal, a polycrystal, and an amorphous body, or in a state in which these are mixed.

FIG. 2B is a sectional view schematically illustrating a second example of the acoustic wave resonator of the multiplexer 1 according to the present example embodiment. In the example of the acoustic wave resonator 60 illustrated in FIG. 2A, the IDT electrode 54 is provided on the piezoelectric substrate 50 including the piezoelectric film 53, but the substrate on which the IDT electrode 54 is provided may be, for example, a piezoelectric single crystal substrate 57 made of a single piezoelectric layer as illustrated in FIG. 2B.

The piezoelectric single crystal substrate 57 is made of, for example, LiNbO₃ piezoelectric single crystal. The acoustic wave resonator according to the present example embodiment includes the LiNbO₃ piezoelectric single crystal substrate 57, the IDT electrode 54, and a protection layer 58 provided on the piezoelectric single crystal substrate 57 and the IDT electrode 54.

The multilayer structure, the material, the cut angle,

and the thickness of the piezoelectric film 53 and the piezoelectric single crystal substrate 57 described above may appropriately be changed in accordance with required bandpass characteristics of an acoustic wave filter device. Even the acoustic wave resonator using a LiTaO₃ piezoelectric substrate or the like having a cut angle other than the above-described cut angle may achieve the same or substantially the same advantageous effects as that of the acoustic wave resonator 60 using the piezoelectric film 53.

The substrate on which the IDT electrode 54 is provided may have a structure in which a support substrate, an energy confinement layer, and a piezoelectric film are laminated in this order. The IDT electrode 54 is provided on the piezoelectric film. The piezoelectric film is made of, for example, LiTaO₃piezoelectric single crystal or piezoelectric ceramics. The support substrate is a substrate that supports the piezoelectric film, the energy confinement layer, and the IDT electrode 54.

The energy confinement layer includes one or more layers, and a velocity of a bulk acoustic wave propagating through at least one of the layers is higher than a velocity of an acoustic wave propagating in the vicinity of the piezoelectric film. For example, the energy confinement layer may have a multilayer structure including a low acoustic velocity layer and a high acoustic velocity layer. The low acoustic velocity layer is a film in which an acoustic velocity of a bulk wave in the low acoustic velocity layer is lower than an acoustic velocity of an acoustic wave propagating through the piezoelectric film. The high acoustic velocity layer is a film in which an acoustic velocity of a bulk wave in the high acoustic velocity layer is higher than an acoustic velocity of an acoustic wave propagating through the piezoelectric film. The support substrate may be, for example, a high acoustic velocity layer.

The energy confinement layer may be an acoustic impedance layer having a configuration in which a low acoustic impedance layer having a relatively low acoustic impedance and a high acoustic impedance layer having a relatively high acoustic impedance are alternately laminated.

Here, electrode parameters of the IDT electrode 54 of the acoustic wave resonator 60 will be described.

A wavelength of an acoustic wave resonator is defined by a wavelength λ illustrated in (b) of FIG. 2A which is a repetition period of the plurality of electrode fingers 61a or 61b of the IDT electrode 54. An electrode finger pitch is about half of the wavelength A, and is defined as (W+S), in which W is a line width of the electrode fingers 61a and 61b respectively defining the comb-shaped electrodes 60a and 60b, and S is a space width between the electrode finger 61a and the electrode finger 61b adjacent to each other.

In the IDT electrode 54, when an interval between adjacent electrode fingers is not constant, the electrode finger pitch of the IDT electrode 54 is defined by an average electrode finger pitch of the IDT electrode 54. The average electrode finger pitch of the IDT electrode 54 is defined as Di/(Ni−1), in which Ni is the total number of the electrode fingers 61a and 61b included in the IDT electrode 54, and Di is a center-to-center distance between an electrode finger positioned at one end and an electrode finger positioned at the other end in the acoustic wave propagation direction of the IDT electrode 54.

FIG. 2C is a sectional view schematically illustrating a third example of the acoustic wave resonator defining the multiplexer 1 according to the present example embodiment. In FIG. 2C, a bulk acoustic wave resonator is illustrated as the acoustic wave resonator of the multiplexer 1. As illustrated in FIG. 2C, the bulk acoustic wave resonator includes, for example, a support substrate 65, a lower electrode 66, a piezoelectric layer 67, and an upper electrode 68, and has a configuration in which the support substrate 65, the lower electrode 66, the piezoelectric layer 67, and the upper electrode 68 are laminated in this order.

The support substrate 65 is a substrate to support the lower electrode 66, the piezoelectric layer 67, and the upper electrode 68, and is a silicon substrate, for example. The support substrate 65 includes a cavity in a region in contact with the lower electrode 66. This makes it possible for the piezoelectric layer 67 to freely vibrate.

The lower electrode 66 is provided on one surface of the support substrate 65. The upper electrode 68 is provided above one surface of the support substrate 65. The lower electrode 66 and the upper electrode 68 each use, for example, Al including about 1% of Cu as the material.

The piezoelectric layer 67 is provided between the lower electrode 66 and the upper electrode 68. The piezoelectric layer 67 includes at least one of materials below as a main component. The materials are, for example, zinc oxide (ZnO), aluminum nitride (AlN), lead zirconate titanate (PZT), potassium niobate (KN), lithium niobate (LN), lithium tantalate (LT), quartz, and lithium borate (LiBO).

bulk acoustic wave resonator having the above-described multilayer structure generates resonance by inducing a bulk acoustic wave in the piezoelectric layer 67 by applying electrical energy between the lower electrode 66 and the upper electrode 68. A bulk acoustic wave generated by the bulk acoustic wave resonator propagates between the lower electrode 66 and the upper electrode 68 in a direction perpendicular to a film surface of the piezoelectric layer 67. That is, the bulk acoustic wave resonator is a resonator using a bulk acoustic wave.

### 4. Resonance Characteristics of Filter 10 and Bandpass

Characteristics of Filter 20

First, a basic operation principle of a ladder band pass filter including one series-arm resonator and one parallel-arm resonator will be described.

A parallel-arm resonator has a resonant frequency frp and an anti-resonant frequency fap (>frp), and a series-arm resonator has a resonant frequency frs and an anti-resonant frequency fas (>frs>frp). In the series-arm resonator and the parallel-arm resonator having the above-described resonance characteristics, in many cases, the anti-resonant frequency fap of the parallel-arm resonator and the resonant frequency frs of the series-arm resonator are made close to each other. Thus, the vicinity of the resonant frequency frp, at which the impedance of the parallel-arm resonator approaches zero, becomes a low frequency side stopband. When the frequency increases from the vicinity of the resonant frequency frp, the impedance of the parallel-arm resonator increases in the vicinity of the anti-resonant frequency fap, and the impedance of the series-arm resonator approaches 0 in the vicinity of the resonant frequency frs. Thus, the vicinity of the anti-resonant frequency fap to the resonant frequency frs becomes a signal pass band in a signal path being the series-arm path. Accordingly, a pass band that reflects electrode parameters and an electromechanical coupling coefficient of the acoustic wave resonator may be provided. Further, when the frequency increases to the vicinity of the anti-resonant frequency fas, the impedance of the series-arm resonator increases, and the vicinity of the anti-resonant frequency fas becomes a high frequency side stopband.

In each of the series-arm resonator and the parallel-arm resonator, the impedance of the resonator exhibits a capacitive property (C property) in a frequency band on a lower frequency side than the resonant frequency, and the impedance of the resonator exhibits an inductive property (L property) in a frequency band on a higher frequency side than the resonant frequency and on a lower frequency side than the anti-resonant frequency. In a frequency band on a higher frequency side than the anti-resonant frequency, the impedance of the resonator exhibits the capacitive property.

Besides the above-described basic operation principle, a multiplexer having a required specification of a narrow band and a small inter-band gap may be configured by adjusting a resonant frequency and an anti-resonant frequency of each of a plurality of acoustic wave resonators each having a relatively large resonance band width.

Next, the resonance characteristics of the series-arm resonator of the filter 10 and the bandpass characteristics of the multiplexer 1 (filter 20) that reflects the resonance characteristics will be described.

Table 1 illustrates the wavelength λ (electrode finger pitch×2) of each resonator of the multiplexer 1 according to the example embodiment.

TABLE 1

| Filter 10 | | | Filter 20 | | |
|---|---|---|---|---|---|
| | | Wavelength λ | | | Wavelength λ |
| | | (μm) | | | (μm) |
| Series-arm | Acoustic wave | 1.6539 | Series-arm | | 1.6169 |
| resonator s11 | resonator 71 | | resonator s21 | | |
| Series-arm | | 1.6624 | Series-arm | | 1.6197 |
| resonator s12 | | | resonator s22 | | |
| Series-arm | Acoustic wave | 1.6621 | Series-arm | | 1.6278 |
| resonator s13 | resonator 72 | | resonator s23 | | |
| | Acoustic wave | 1.6969 | | | |
| | resonator 73 | | | | |
| Series-arm | | 1.6575 | Series-arm | Acoustic wave | 1.6252 |
| resonator s14 | | | resonator s24 | resonator 81 | |
| | | | | Acoustic wave | 1.6787 |
| | | | | resonator 82 | |
| | | | Series-arm | | 1.6170 |
| | | | resonator s25 | | |
| Parallel-arm | | 1.7284 | Parallel-arm | | 1.6621 |
| resonator p11 | | | resonator p21 | | |
| Parallel-arm | Acoustic wave | 1.7290 | Parallel-arm | | 1.6768 |
| resonator p12 | resonator 74 | | resonator p22 | | |
| | Acoustic wave | 1.6823 | | | |
| | resonator 75 | | | | |
| Parallel-arm | | 1.7326 | Parallel-arm | Acoustic wave | 1.7015 |
| resonator p13 | | | resonator p23 | resonator 83 | |
| | | | | Acoustic wave | 1.6209 |
| | | | | resonator 84 | |
| Parallel-arm | | 1.7195 | Parallel-arm | | 1.6662 |
| resonator p14 | | | resonator p24 | | |

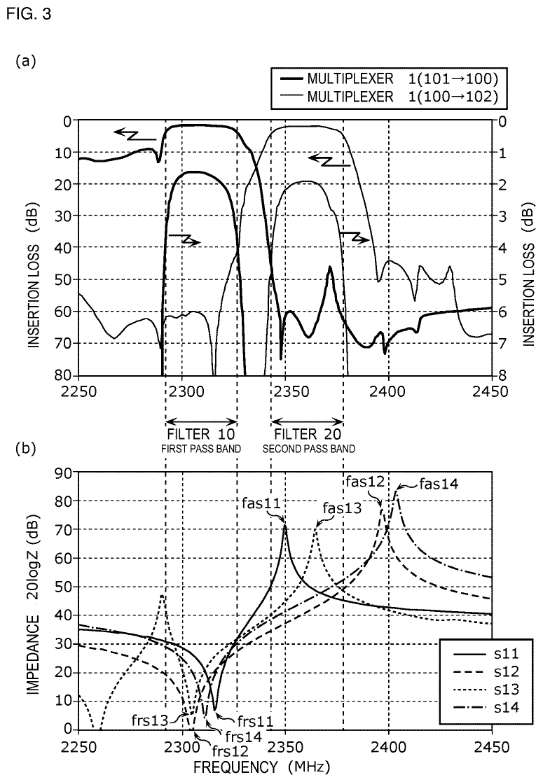

FIG. 3 is a graph illustrating (a) a bandpass characteristic of the multiplexer 1 and (b) an impedance characteristic of each of the series-arm resonators s11 to s14 of the filter 10 according to an example embodiment.

In (b) of FIG. 3, the resonant frequency frs11 of the series-arm resonator s11, a resonant frequency frs12 of the series-arm resonator s12, a resonant frequency frs13 of the series-arm resonator s13, a resonant frequency frs14 of the series-arm resonator s14 are positioned within the first pass band of the filter 10. On the other hand, the anti-resonant frequency fas11 of the series-arm resonator s11, an anti-resonant frequency fas12 of the series-arm resonator s12, an anti-resonant frequency fas13 of the series-arm resonator s13, and an anti-resonant frequency fas14 of the series-arm resonator s14 are positioned on a higher frequency side than a high frequency end of the first pass band of the filter 10.

With the acoustic wave resonators 72 and 73 being coupled in parallel, the series-arm resonator s13 has two resonant frequencies and two anti-resonant frequencies. The resonant frequency frs13 is defined as a high frequency side resonant frequency of the two resonant frequencies, and the anti-resonant frequency fas13 is defined as a high frequency side anti-resonant frequency of the two anti-resonant frequencies.

The resonance band width of at least one of the series-arm resonators s11 to s14 included in the filter 10 is wider than the first pass band.

Alternatively, the electrode finger pitch of the IDT electrode of at least one of the series-arm resonators s11 to s14 included in the filter 10 is smaller than the electrode finger pitch of the IDT electrode of at least one of the parallel-arm resonators p21 to p24 included in the filter 20. In other words, the resonant frequency of at least one of the series-arm resonators s11 to s14 included in the filter 10 is higher than the resonant frequency of at least one of the parallel-arm resonators p21 to p24 included in the filter 20. That is, the inter-passband gap between the first pass band and the second pass band is narrower than the resonance band width of at least one of the series-arm resonators s11 to s14 included in the filter 10. As illustrated in Table 1, in the present example embodiment, the wavelength A (electrode finger pitch×2) of each of the series-arm resonators s11 and s14 is smaller than the wavelength λ (electrode finger pitch×2) of each of the parallel-arm resonators p21 to p24.

In contrast, the anti-resonant frequency fas11 of the series-arm resonator s11 is lower than a high frequency end of the second pass band and is lowest among the anti-resonant frequencies fas11 to fas14 of the series-arm resonators s11 to s14 included in the filter 10.

The resonant frequency frs11 of the series-arm resonator s11 is higher than a low frequency end of the first pass band. With the configuration above, the series-arm resonator s11 does not shift both of the resonant frequency frs11 and the anti-resonant frequency fas11 to a low frequency side by increasing the electrode finger pitch, but shifts only the anti-resonant frequency fas11 to a low frequency side by decreasing the resonance band width. This makes it possible for the resonant frequency frs11 to be positioned within the first pass band, and thus insertion loss in the first pass band of the filter 10 may be reduced.

The series-arm resonators s11 to s14 included in the filter 10 are resonators that contribute to the formation of the first pass band, and specifically, resonators in which at least a portion of a frequency region sandwiched by the resonant frequency and the anti-resonant frequency overlaps with the first pass band. In other words, the plurality of series-arm resonators included in the filter 10 are resonators that contribute to the formation of the first pass band, and do not include a resonator in which at least a portion of a frequency region sandwiched by the resonant frequency and the anti-resonant frequency does not overlap with the first pass band.

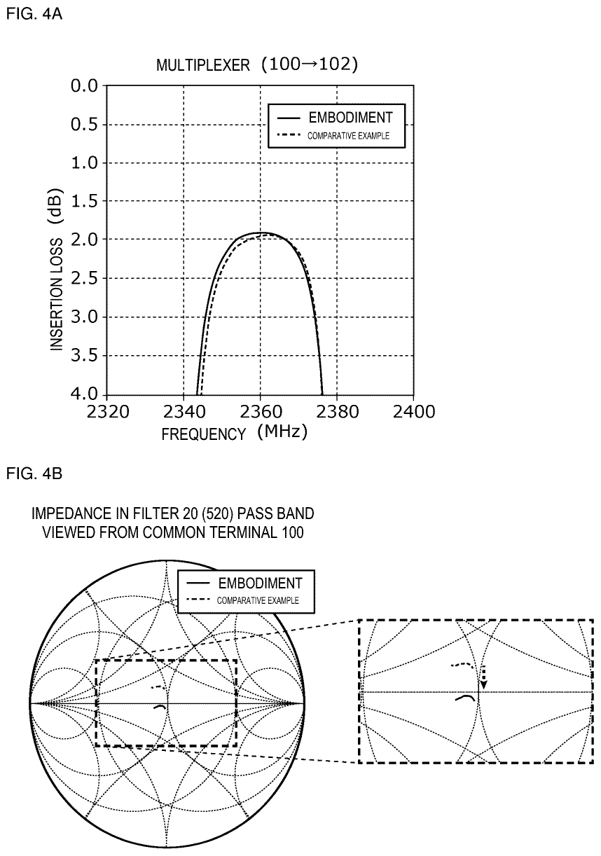

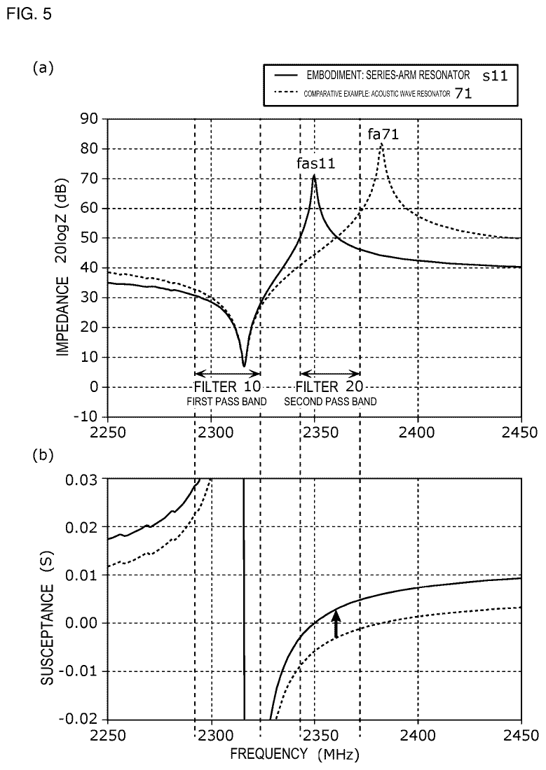

FIG. 4A is a graph illustrating a bandpass characteristic of the filter 20 (filter 520) in the multiplexer according to the present example embodiment and a multiplexer according to the comparative example. FIG. 4B is an immittance chart illustrating impedance in the second pass band of the multiplexer according to each of the present example embodiment and the comparative example when viewed from the common terminal 100. FIG. 5 is a graph illustrating an impedance characteristic and a susceptance characteristic of the first series-arm resonator according to each of the present example embodiment and the comparative example.

The multiplexer according to the comparative example includes filters 510 and 520 instead of the filters 10 and 20. The multiplexer according to the comparative example is different from the multiplexer 1 according to the present example embodiment in the configuration of the filters 510 and 520. The filter 510 is different from the filter 10 only in that the capacitor 91 is not coupled to the acoustic wave resonator 71 in parallel. The filter 520 is different from the filter 20 only in that an acoustic wave resonator 80 is provided instead of the series-arm resonator s21.

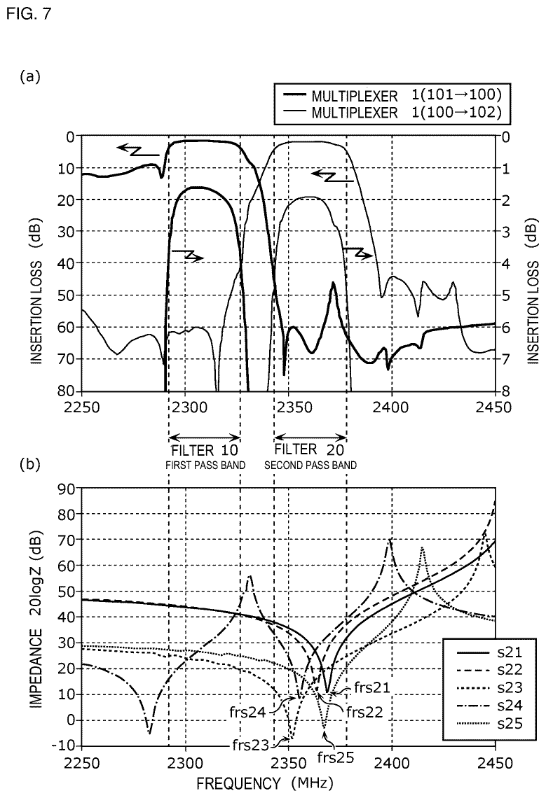

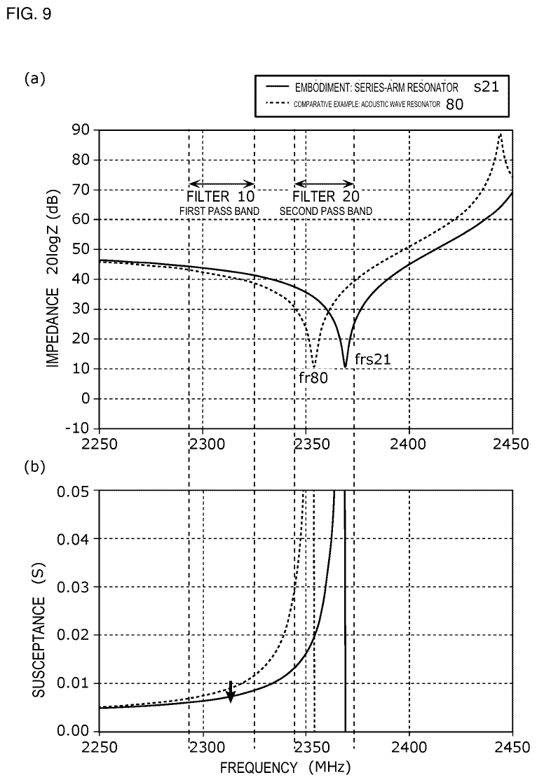

Specifically, in the multiplexer according to the comparative example, the first series-arm resonator coupled closest to the common terminal 100 is the acoustic wave resonator 71, and as illustrated in (a) of FIG. 5, the anti-resonant frequency fa71 of the acoustic wave resonator 71 is positioned on a higher frequency side than the high frequency end of the second pass band. Further, in the multiplexer according to the comparative example, the second series-arm resonator coupled closest to the common terminal 100 is the acoustic wave resonator 80, and as illustrated in (a) of FIG. 9 and (b) of FIG. 7, a resonant frequency fr80 of the acoustic wave resonator 80 is lower than a resonant frequency frs22 of the series-arm resonator s22, a resonant frequency frs24 of the series-arm resonator s24, and a resonant frequency frs25 of the series-arm resonator s25.

In the multiplexer according to the comparative example, as illustrated in (a) of FIG. 5, a resonance band width of the acoustic wave resonator 71 is wide, and thus an inductive region (region between the resonant frequency fr71 and the anti-resonant frequency fa71) of the acoustic wave resonator 71 overlaps with the second pass band. In other words, in the multiplexer according to the comparative example, as illustrated in (b) of FIG. 5, a region in which the susceptance of the acoustic wave resonator 71 is small overlaps with the second pass band. With the configuration above, in multiplexer according to the comparative example, the acoustic wave resonator 71, among the acoustic wave resonators of the filter 510, is coupled closest to the filter 520 in series, and thus, as illustrated in FIG. 4B, the impedance in the second pass band when the filters 510 and 520 are viewed from the common terminal 100 deviates from the impedance (reference impedance) in the second pass band optimized by the filter 520 alone into the inductive region (broken line in FIG. 4B).

In contrast, in the multiplexer 1 according to the present example embodiment, as illustrated in (a) of FIG. 5, the resonance band width of the series-arm resonator s11 is narrower than that of the acoustic wave resonator 71, and thus the overlap of the second pass band and the inductive region of the series-arm resonator s11 is reduced. In other words, in the multiplexer 1 according to the present example embodiment, as illustrated in (b) of FIG. 5, a region in which the susceptance of the series-arm resonator s11 is large overlaps with the second pass band. Thus, in the multiplexer 1 according to the present example embodiment, as illustrated in FIG. 4B, the impedance in the second pass band when the filters 10 and 20 are viewed from the common terminal 100 may be positioned closer to the impedance (reference impedance) (solid line in FIG. 4B) in the second pass band optimized by the filter 20 alone than in the multiplexer according to the comparative example.

With the configuration above, as illustrated in FIG. 4A, the bandpass characteristics of the filter 20 (bandpass characteristics from common terminal 100 to output terminal 102) of the multiplexer 1 according to the present example embodiment may lower insertion loss in the second pass band, as compared with the bandpass characteristics of the filter 520 of the multiplexer according to the comparative example.

In the present example embodiment, by coupling the capacitor 91 in parallel to the first series-arm resonator coupled closest to the common terminal 100 among the series-arm resonators and the parallel-arm resonators of the filter 10, the resonance band width is narrowed. However, the configuration to narrow the resonance band width is not limited thereto.

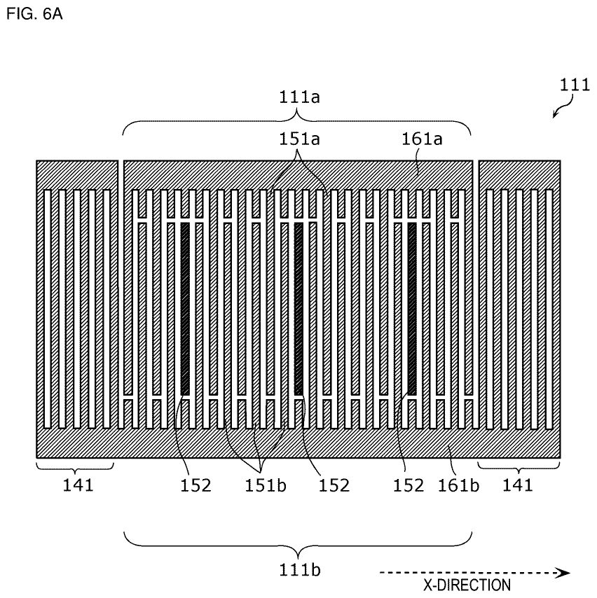

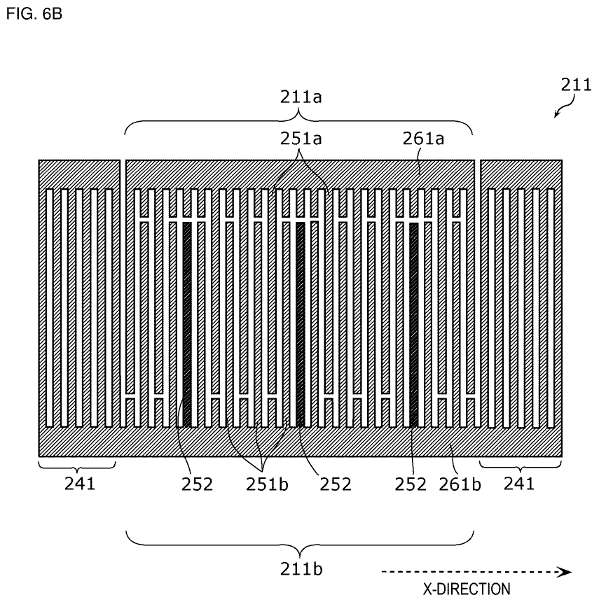

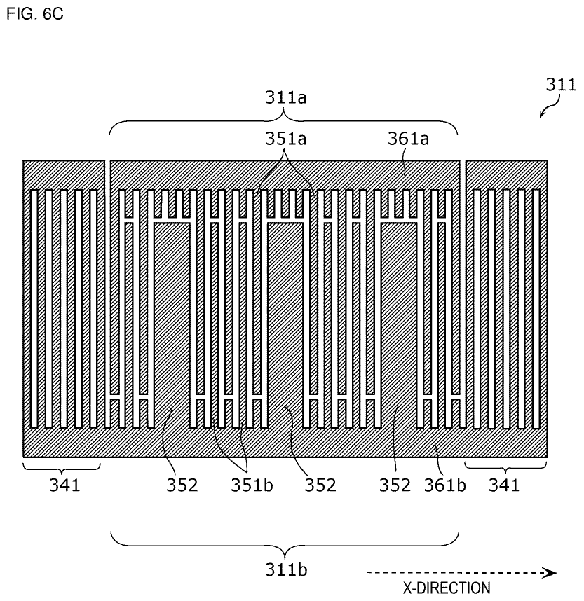

The configuration to narrow the resonance band width of the first series-arm resonator includes providing a withdrawal electrode in the IDT electrode of the first series-arm resonator. The IDT electrode of the first series-arm resonator may include, for example, any of a floating withdrawal electrode illustrated in FIG. 6A, a polarity-inverted withdrawal electrode illustrated in FIG. 6B, and a filled-in withdrawal electrode illustrated in FIG. 6C. With the configurations above, the resonance band width of the first series-arm resonator becomes narrow, and the anti-resonant frequency may be made low.

FIG. 6A is a schematic plan view illustrating a

configuration of an IDT electrode including the floating withdrawal electrode. FIG. 6B is a schematic plan view illustrating a configuration of an IDT electrode including the polarity-inverted withdrawal electrode. FIG. 6C is a schematic plan view illustrating a configuration of an IDT electrode including the filled-in withdrawal electrode.

An acoustic wave resonator 111 illustrated in FIG. 6A is an example of the first series-arm resonator, and exemplifies an electrode finger structure of an IDT electrode including the floating withdrawal electrode. The acoustic wave resonator 111 illustrated in FIG. 6A is provided to describe a typical structure of the floating withdrawal electrode, and the number, length, and the like of electrode fingers of the electrode are not limited to those of the electrode fingers of the electrode in the acoustic wave resonator 111.

The acoustic wave resonator 111 is constituted of the piezoelectric substrate 50, comb-shaped electrodes 111a and 111b and a reflector 141 formed on the piezoelectric substrate 50.

As illustrated in FIG. 6A, the comb-shaped electrode 111a includes a plurality of electrode fingers 151a parallel to each other and a busbar electrode 161a coupling one ends of the plurality of electrode fingers 151a to each other. The comb-shaped electrode 111b includes a plurality of electrode fingers 151b parallel to each other and a busbar electrode 161b coupling one ends of the plurality of electrode fingers 151b to each other. The plurality of electrode fingers 151a and 151b are arranged in the direction orthogonal to a propagation direction of the surface acoustic wave (X-axis direction). The comb-shaped electrodes 111a and 111b are disposed to face each other such that the plurality of electrode fingers 151a and 151b are interdigitated with each other. That is, the IDT electrode of the acoustic wave resonator 111 includes a pair of the comb-shaped electrodes 111a and 111b.

The comb-shaped electrode 111a includes a dummy electrode disposed to face the plurality of electrode fingers 151b in a longitudinal direction, but the dummy electrode may be omitted. The comb-shaped electrode 111b includes a dummy electrode disposed to face the plurality of electrode fingers 151a in the longitudinal direction, but the dummy electrode may be omitted. The comb-shaped electrodes 111a and 111b may be, for example, an inclined IDT electrode in which an extending direction of the busbar electrode is inclined relative to the propagation direction of the surface acoustic wave, or may have a piston structure.

The reflector 141 includes a plurality of electrode fingers parallel to each other and busbar electrodes coupling the plurality of electrode fingers, and the reflectors 141 are disposed at both ends of the pair of the comb-shaped electrodes 111a and 111b.

Here, electrode fingers 152 are discretely provided in the IDT electrode of the acoustic wave resonator 111. The electrode fingers 152 are coupled to neither of the busbar electrodes 161a nor 161b, and are floating withdrawal electrodes disposed in parallel to the plurality of electrode fingers 151a and 151b, and with the same or substantially the same pitch. The plurality of electrode fingers 151a and 151b are disposed between two adjacent electrode fingers 152. That is, a pitch of the electrode fingers 152 is larger than a pitch of the plurality of electrode fingers 151a and 151b.

An acoustic wave resonator 211 illustrated in FIG. 6B is an example of the first series-arm resonator, and exemplifies an electrode finger structure of an IDT electrode including the polarity-inverted withdrawal electrode. The acoustic wave resonator 211 illustrated in FIG. 6B is provided to describe a typical structure of the polarity-inverted withdrawal electrode, and the number, length, and the like of electrode fingers of the electrode are not limited to those of the electrode fingers of the electrode in the acoustic wave resonator 211.

The acoustic wave resonator 211 includes the piezoelectric substrate 50, comb-shaped electrodes 211a and 211b and a reflector 241 on the piezoelectric substrate 50.

As illustrated in FIG. 6B, the comb-shaped electrode 211a includes a plurality of electrode fingers 251a parallel to each other and a busbar electrode 261a coupling one ends of the plurality of electrode fingers 251a to each other. The comb-shaped electrode 211b includes a plurality of electrode fingers 251b parallel to each other and a busbar electrode 261b coupling one ends of the plurality of electrode fingers 251b to each other. The plurality of electrode fingers 251a and 251b are arranged in the direction orthogonal to the propagation direction of the surface acoustic wave (X-axis direction). The comb-shaped electrodes 211a and 211b are disposed to face each other such that the plurality of electrode fingers 251a and 251b are interdigitated with each other. That is, the IDT electrode of the acoustic wave resonator 211 includes a pair of the comb-shaped electrodes 211a and 211b.

The comb-shaped electrode 211a includes a dummy electrode facing the plurality of electrode fingers 251b in a longitudinal direction, but the dummy electrode may be omitted. The comb-shaped electrode 211b includes a dummy electrode facing the plurality of electrode fingers 251a in the longitudinal direction, but the dummy electrodes may be omitted. The comb-shaped electrodes 211a and 211b may be, for example, an inclined IDT electrode in which the extending direction of the busbar electrode is inclined relative to the propagation direction of the surface acoustic wave, or may have a piston structure.

The reflector 241 includes a plurality of electrode fingers parallel to each other and busbar electrodes coupling the plurality of electrode fingers, and the reflectors 241 are disposed at both ends of the pair of the comb-shaped electrodes 211a and 211b.

Here, electrode fingers 252 are discretely provided in

the IDT electrode of the acoustic wave resonator 211. The electrode finger 252 is the polarity-inverted withdrawal electrode coupled to the same busbar electrode as the busbar electrode to which the electrode fingers on both sides of the electrode finger 252, among all the electrode fingers of the pair of the comb-shaped electrodes 211a and 211b, are coupled. The plurality of electrode fingers 251a and 251b are disposed between two adjacent electrode fingers 252. That is, a pitch of the electrode fingers 252 is larger than a pitch of the plurality of electrode fingers 251a and 251b.

An acoustic wave resonator 311 illustrated in FIG. 6C is an example of the first series-arm resonator, and exemplifies an electrode finger structure of an IDT electrode including the filled-in withdrawal electrode. The acoustic wave resonator 311 illustrated in FIG. 6C is provided to describe a typical structure of the filled-in withdrawal electrode, and the number, length, and the like of electrode fingers of the electrode are not limited to those of the electrode fingers of the electrode in the acoustic wave resonator 311.

The acoustic the wave resonator 311 includes piezoelectric substrate 50, comb-shaped electrodes 311a and 311b and a reflector 341 on the piezoelectric substrate 50.

As illustrated in FIG. 6C, the comb-shaped electrode 311a includes a plurality of electrode fingers 351a parallel to each other and a busbar electrode 361a coupling one ends of the plurality of electrode fingers 351a to each other. The comb-shaped electrodes 311b includes a plurality of electrode fingers 351b parallel to each other and a busbar electrode 361b coupling one ends of the plurality of electrode fingers 351b to each other. The plurality of electrode fingers 351a and 351b are arranged in the direction orthogonal to the propagation direction of the surface acoustic wave (X-axis direction). The comb-shaped electrodes 311a and 311b are disposed to face each other such that the plurality of electrode fingers 351a and 351b are interdigitated with each other. That is, the IDT electrode of the acoustic wave resonator 311 includes a pair of the comb-shaped electrodes 311a and 311b.

The comb-shaped electrode 311a includes a dummy electrode facing the plurality of electrode fingers 351b in a longitudinal direction, but the dummy electrode may be omitted. The comb-shaped electrode 311b includes a dummy electrode facing the plurality of electrode fingers 351a in the longitudinal direction, but the dummy electrode may be omitted. The comb-shaped electrodes 311a and 311b may be, for example, an inclined IDT electrode in which the extending direction of the busbar electrode is inclined relative to the propagation direction of the surface acoustic wave, or may have a piston structure.

The reflector 341 includes a plurality of electrode fingers parallel to each other and busbar electrodes coupling the plurality of electrode fingers, and the reflectors 341 are disposed at both ends of the pair of the comb-shaped electrodes 311a and 311b.

Here, electrode fingers 352 are discretely provided in the IDT electrode of the acoustic wave resonator 311. The electrode finger 352 is an electrode finger having the largest electrode finger width in the IDT electrode of the acoustic wave resonator 311, and is the filled-in withdrawal electrode having an electrode finger width that is about twice or more an average electrode finger width of the electrode fingers excluding the electrode finger 352. In other words, the electrode finger 352 is made into one electrode finger with the adjacent electrode fingers 351a and 351b and the space between the adjacent electrode fingers 351a and 351b being combined (three electrode fingers including electrode fingers 351a and 351b are combined in FIG. 6C). The electrode finger 352 is coupled to either the busbar electrode 361a or the busbar electrode 361b, and is the filled-in withdrawal electrode having an electrode finger width wider than that of each of the plurality of electrode fingers 351a and 351b. The plurality of electrode fingers 351a and 351b are disposed between two adjacent electrode fingers 352. That is, a pitch of the electrode fingers 352 is larger than a pitch of the plurality of electrode fingers 351a and 351b.

The configuration of the withdrawal electrode, which is provided to reduce the resonance band width of the first series-arm resonator, is not limited to the floating withdrawal electrode, the polarity-inverted withdrawal electrode, and the filled-in withdrawal electrode described above.

Further, the configuration to reduce the resonance band width of the first series-arm resonator includes adjusting the film thickness of the dielectric film disposed on the IDT electrode of the first series-arm resonator. In the acoustic wave resonator 60 illustrated in (b) of FIG. 2A, the protection layer 55 is an example of a first dielectric film, and a resonance band width of the acoustic wave resonator 60 may be changed by adjusting a film thickness of the protection layer 55. Specifically, the resonance band width decreases as the film thickness of the protection layer 55 increases.

From the viewpoint above, the first series-arm resonator may have the thickest protection layer 55 (first dielectric film) among the series-arm resonators of the filter 10. With the configuration above, the resonance band width of the first series-arm resonator becomes narrow, and the anti-resonant frequency may be made low.

The first dielectric film is not necessarily the protection layer 55 provided on the IDT electrode, and may be a dielectric film provided between the piezoelectric substrate 50 and the IDT electrode.

### 5. Resonance Characteristics of Filter 20 and Bandpass Characteristics of Filter 10

Next, the resonance characteristics of the series-arm resonator of the filter 20 and the bandpass characteristics of the multiplexer 1 (filter 10) that reflects the resonance characteristics will be described.

FIG. 7 is a graph illustrating (a) the bandpass characteristics of the multiplexer 1 and (b) an impedance characteristic of each of the series-arm resonators s21 to s25 of the filter 20 according to the present example embodiment.

In (b) of FIG. 7, a resonant frequency frs21 of the series-arm resonator s21, the resonant frequency frs22 of the series-arm resonator s22, a resonant frequency frs23 of the series-arm resonator s23, the resonant frequency frs24 of the series-arm resonator s24, and the resonant frequency frs25 of the series-arm resonator s25 are positioned within the second pass band of the filter 20.

With the acoustic wave resonators 81 and 82 being coupled in parallel, the series-arm resonator s24 has two resonant frequencies and two anti-resonant frequencies, and the resonant frequency frs24 is defined as a high frequency side resonant frequency of the two resonant frequencies.

The resonance band width of at least one of the series-arm resonators s21 to s25 of the filter 20 is wider than the second pass band.

Alternatively, the electrode finger pitch of the IDT electrode of at least one of the series-arm resonators s11 to s14 included in the filter 10 is smaller than the electrode finger pitch of the IDT electrode of at least one of the parallel-arm resonators p21 to p24 included in the filter 20. In other words, the resonant frequency of at least one of the series-arm resonators s11 to s14 included in the filter 10 is higher than the resonant frequency of at least one of the parallel-arm resonators p21 to p24 included in the filter 20. That is, the inter-passband gap between the first pass band and the second pass band is narrower than the resonance band width of at least one of the series-arm resonators s21 to s25 included in the filter 20. As illustrated in Table 1, in the present example embodiment, the wavelength λ (electrode finger pitch×2) of each of the series-arm resonators s11 and s14 is smaller than the wavelength λ (electrode finger pitch×2) of each of the parallel-arm resonators p21 to p24.

In contrast, the resonant frequency frs21 of the series-

arm resonator s21 is higher than the high frequency end of the first pass band, and is highest among the resonant frequencies frs21 to frs25 of the series-arm resonators s21 to s25. Alternatively, as illustrated in Table 1, the IDT electrode of the series-arm resonator s21 has the smallest electrode finger pitch among the IDT electrodes of the series-arm resonators s21 to s25.

The series-arm resonators s21 to s25 included in the filter 20 are resonators that contribute to the formation of the second pass band, and specifically, resonators in which at least a portion of a frequency region sandwiched by the resonant frequency and the anti-resonant frequency overlaps with the second pass band. In other words, the plurality of series-arm resonators included in the filter 20 are resonators that contribute to the formation of the second pass band, and do not include a resonator in which at least a portion of a frequency region sandwiched by the resonant frequency and the anti-resonant frequency does not overlap with the second pass band.

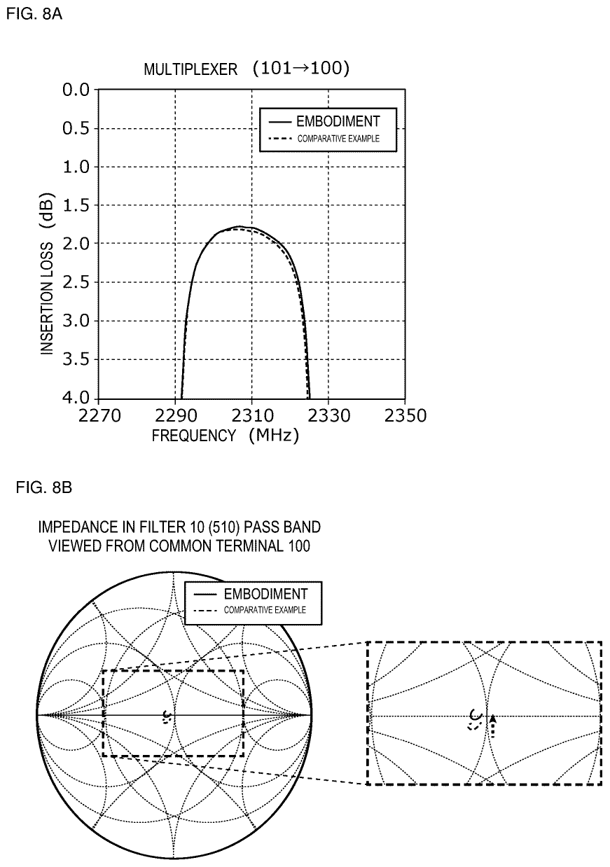

FIG. 8A is a graph illustrating a bandpass characteristic of the filter 10 (filter 510) in the multiplexer according to each of the present example embodiment and the comparative example. FIG. 8B is an immittance chart illustrating impedance in the first pass band of the multiplexer according to each of the present example embodiment and the comparative example when viewed from the common terminal 100. FIG. 9 is a graph illustrating an impedance characteristic and a susceptance characteristic of the second series-arm resonator according to each of the present example embodiment and the comparative example.

The multiplexer according to the comparative example includes filters 510 and 520 instead of the filters 10 and 20. The multiplexer according to the comparative example is different from the multiplexer 1 according to the present example embodiment in the configuration of the filters 510 and 520. The filter 510 is different from the filter 10 only in that the capacitor 91 is not coupled to the acoustic wave resonator 71 in parallel. The filter 520 is different from the filter 20 only in that the acoustic wave resonator 80 is provided instead of the series-arm resonator s21.

Specifically, in the multiplexer according to the comparative example, the first series-arm resonator coupled closest to the common terminal 100 is the acoustic wave resonator 71, and as illustrated in (a) of FIG. 5, the anti-resonant frequency fa71 of the acoustic wave resonator 71 is positioned on a higher frequency side than the high frequency end of the second pass band. Further, in the multiplexer according to the comparative example, the second series-arm resonator coupled closest to the common terminal 100 is the acoustic wave resonator 80, and as illustrated in (a) of FIG. 9 and (b) of FIG. 7, the resonant frequency fr80 of the acoustic wave resonator 80 is lower than the resonant frequency frs22 of the series-arm resonator s22, the resonant frequency frs24 of the series-arm resonator s24, and the resonant frequency frs25 of the series-arm resonator s25.

In the multiplexer according to the comparative example, as illustrated in (a) of FIG. 9, a resonance band width of the acoustic wave resonator 80 is wide, and thus the capacitive region (region on a lower frequency side than the resonant frequency fr80) of the acoustic wave resonator 80 overlaps with the first pass band of the filter 10. In other words, in the multiplexer according to the comparative example, as illustrated in (b) of FIG. 9, a region in which susceptance of the acoustic wave resonator 80 is large overlaps with the first pass band of the filter 10. With the configuration described above, in the multiplexer according to the comparative example, as illustrated in FIG. 8B, the acoustic wave resonator 80, among the acoustic wave resonators of the filter 20, is coupled closest to the filter 10 in series, and thus the impedance in the first pass band when the filters 10 and 20 are viewed from the common terminal 100 deviates from the impedance (reference impedance) in the first pass band optimized by the filter 10 alone into a capacitive region (broken line in FIG. 8B).

In contrast, in the multiplexer 1 according to the present example embodiment, as illustrated in (a) of FIG. 9, the resonant frequency frs21 of the series-arm resonator s21 is highest among the resonant frequencies frs21 to frs25 of the series-arm resonators s21 to s25, and thus the capacitive region, in which the capacitive property of the series-arm resonator s21 is high, overlaps with the first pass band of the filter 10. In other words, in the multiplexer 1 according to the present example embodiment, as illustrated in (b) of FIG. 9, a region in which susceptance of the series-arm resonator s21 is small overlaps with the first pass band of the filter 10. Thus, in the multiplexer 1 according to the present example embodiment, as illustrated in FIG. 8B, the impedance in the first pass band when the filters 10 and 20 are viewed from the common terminal 100 may be positioned closer to the impedance (reference impedance) (solid line in FIG. 8B) in the first pass band optimized by the filter 10 alone than in the multiplexer according to the comparative example.

With the configuration described above, as illustrated in FIG. 8A, the bandpass characteristics of the filter 10 (bandpass characteristics from input terminal 101 to common terminal 100) of the multiplexer 1 according to the present example embodiment may lower the insertion loss in the first pass band, as compared with the bandpass characteristics of the filter 510 of the multiplexer according to the comparative example.

In the present example e embodiment, the series-arm resonator s21 (second series-arm resonator) is coupled closest to the common terminal 100 among the series-arm resonators and the parallel-arm resonators of the filter 20. By making the electrode finger pitch of the IDT electrode of the series-arm resonator s21 among the series-arm resonators s21 to s25 included in the filter 20 smallest, the resonant frequency frs21 is made highest, but the configuration to make the resonant frequency frs21 high is not limited thereto.

The configuration to make the resonant frequency of the second series-arm resonator high includes that the second series-arm resonator includes a second acoustic wave element and a second capacitance element (bridging capacitance) coupled to the second acoustic wave element in parallel. By adding the second capacitance element (bridging capacitance), the resonance band width of the second series-arm resonator becomes narrower relative to the resonance band width of the second acoustic wave element, and the resonant frequency of the second series-arm resonator may be made high.

Further, the configuration to make the resonant frequency of the second series-arm resonator high includes that the IDT electrode of the second series-arm resonator includes a withdrawal electrode. The IDT electrode of the second series-arm resonator may include any of the floating withdrawal electrode illustrated in FIG. 6A, the polarity-inverted withdrawal electrode illustrated in FIG. 6B, and the filled-in withdrawal electrode illustrated in FIG. 6C. With the configurations above, the resonance band width of the second series-arm resonator becomes narrow, and the resonant frequency thereof may be made high.

The configuration of the withdrawal electrode, which is the configuration to reduce the resonance band width of the second series-arm resonator, is not limited to the floating withdrawal electrode, the polarity-inverted withdrawal electrode, and the filled-in withdrawal electrode described above.

Further, the configuration to reduce the resonance band width of the second series-arm resonator includes adjusting the film thickness of the dielectric film disposed on the IDT electrode of the second series-arm resonator. In the acoustic wave resonator 60 illustrated in (b) of FIG. 2A, the protection layer 55 is an example of the second dielectric film, and the resonance band width of the acoustic wave resonator 60 may be changed by adjusting the film thickness of the protection layer 55. Specifically, the resonance band width decreases as the film thickness of the protection layer 55 increases. From the above viewpoint, the second series-arm resonator may have the thickest protection layer 55 (second dielectric film) among the series-arm resonators of the filter 20. With the configuration above, the resonance band width of the second series-arm resonator becomes narrow, and the resonant frequency thereof may be made high.

The second dielectric film is not necessarily the protection layer 55 provided on the IDT electrode, and may be a dielectric film disposed between the piezoelectric substrate 50 and the IDT electrode.

In the multiplexer 1 according to the present example embodiment, the resonant frequency frp21 of the parallel-arm resonator p21 may have the following features.

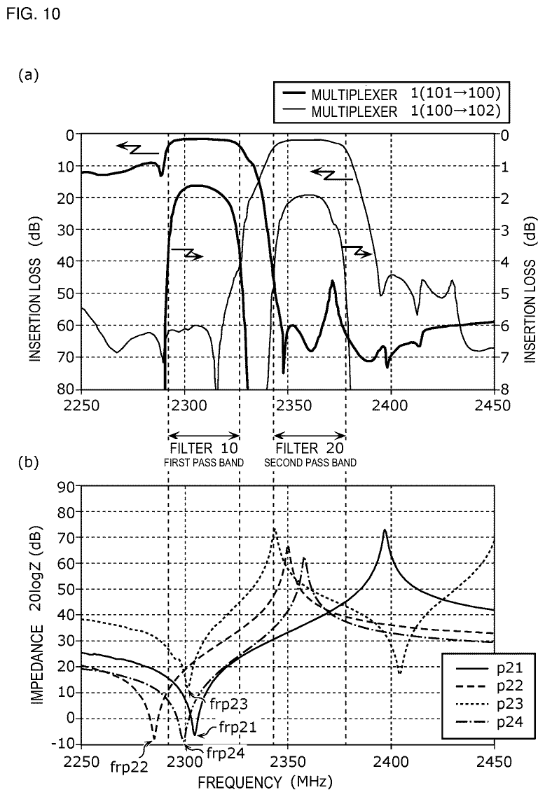

FIG. 10 is a graph illustrating (a) the bandpass characteristics of the multiplexer 1 and (b) an impedance characteristic of each of the parallel-arm resonators p21 to p24 of the filter 20 according to the example embodiment.

In (b) of FIG. 10, the resonant frequency frp21 of the parallel-arm resonator p21 is lower than the high frequency end of the first pass band, and is highest among the resonant frequencies frp21 to frp24 of the parallel-arm resonators p21 to p24.

The parallel-arm resonator p21 is an example of the first parallel-arm resonator and is coupled to the series-arm resonator s21 (second series-arm resonator).

With the acoustic wave resonators 83 and 84 being coupled in series, the parallel-arm resonator p23 has two resonant frequencies and two anti-resonant frequencies, and the resonant frequency frp23 is defined as a low frequency side resonant frequency of the two resonant frequencies.

The parallel-arm resonators p21 to p24 included in the filter 20 are resonators that contribute to the formation of the second pass band, and specifically, resonators in which at least a portion of a frequency region sandwiched by the resonant frequency and the anti-resonant frequency overlaps with the second pass band. In other words, the plurality of parallel-arm resonators included in the filter 20 are resonators that contribute to the formation of the second pass band, and do not include a resonator in which at least a portion of a frequency region sandwiched by the resonant frequency and the anti-resonant frequency does not overlap with the second pass band.

In the multiplexer 1 according to the present example embodiment, as illustrated in (b) of FIG. 10, the resonance band width of each of the parallel-arm resonators p21 to p24 is wider than the first pass band, the second pass band, and the inter-passband gap, and thus the inductive region of each of the parallel-arm resonators p21 to p24 overlaps with the first pass band of the filter 10.

In contrast, since the resonant frequency frp21 of the parallel-arm resonator p21 is highest among the resonant frequencies frp21 to frp24 of the parallel-arm resonators p21 to p24, the inductive property of the parallel-arm resonator p21 in the first pass band may be reduced. This allows the impedance in the first pass band, when the filter 20 alone is viewed from the common terminal 100 side, to be shifted to an open side.

With the configuration above, deviation of the impedance in the first pass band, when the filters 10 and 20 are viewed from the common terminal 100, from the impedance (reference impedance) in the first pass band optimized by the filter 10 alone may be made small. Thus, in the bandpass characteristics (bandpass characteristics from input terminal 101 to common terminal 100) of the filter 10 of the multiplexer 1 according to the present example embodiment, the insertion loss in the first pass band may further be reduced.

### 6. Configuration of Multiplexer According to Example Embodiments of the Present Invention

In the multiplexer 1 according to the present example embodiment, (1) the anti-resonant frequency fas11 of the first series-arm resonator (series-arm resonator s11) is lower than the high frequency end of the second pass band and is lowest among the anti-resonant frequencies fas11 to fas14 of the series-arm resonators s11 to s14 included in the filter 10, and (2) the resonant frequency frs21 of the second series-arm resonator (series-arm resonator s21) is higher than the high frequency end of the first pass band and is highest among the resonant frequencies frs21 to frs25 of the series-arm resonators s21 to s25 included in the filter 20. However, the multiplexer according to the present invention is not limited thereto.

Multiplexers according to example embodiments of the present invention have a feature of at least one of the following: (1) the anti-resonant frequency fas11 of the first series-arm resonator (series-arm resonator s11) is lower than the high frequency end of the second pass band, and is lowest among the anti-resonant frequencies fas11 to fas14 of the series-arm resonators s11 to s14 included in the filter 10, and (2) the resonant frequency frs21 of the second series-arm resonator (series-arm resonator s21) is higher than the high frequency end of the first pass band, and is highest among the resonant frequencies frs21 to frs25 of the series-arm resonators s21 to s25 included in the filter 20.

With the configuration described above, by having the feature (1), in the multiplexer 1, the impedance in the second pass band when the filters 10 and 20 are viewed from the common terminal 100 may be positioned closer to the impedance (reference impedance) in the second pass band optimized by the filter 20 alone than in the multiplexer according to the comparative example. Thus, the insertion loss in the second pass band of the multiplexer 1 may be made lower than the insertion loss in the second pass band of the multiplexer according to the comparative example.

Further, by having the feature (2), in the multiplexer 1, the impedance in the first pass band when the filters 10 and 20 are viewed from the common terminal 100 may be positioned closer to the impedance (reference impedance) in the first pass band optimized by the filter 10 alone than in the multiplexer according to the comparative example. Thus, the insertion loss in the first pass band of the multiplexer 1 may be made lower than the insertion loss in the first pass band of the multiplexer according to the comparative example.

### 7. Advantageous Effects

As described above, the multiplexer 1 according to the present example embodiment includes the filter 10 having the first pass band and the filter 20 having the second pass band on a higher frequency side than the first pass band, and the filters 10 and 20 are coupled to the common terminal 100. The filter 10 includes two or more series-arm resonators s11 to s14 each including an acoustic wave resonator and provided in a series-arm path coupling the input end and the output end, and one or more parallel-arm resonators p11 to p14 each including an acoustic wave resonator and coupled between the series-arm path and the ground. The resonance band width of at least one of the series-arm resonators s11 to s14 is wider than the first pass band. The series-arm resonator s11 (first series-arm resonator) is coupled closest to the common terminal 100 among the series-arm resonators s11 to s14 and the parallel-arm resonators p11 to p14. The anti-resonant frequency fas11 of the series-arm resonator s11 is lower than the high frequency end of the second pass band and is lowest among the anti-resonant frequencies positioned on a higher frequency side than the first pass band among the anti-resonant frequencies fas11 to fas14 of the series-arm resonators s11 to s14.

With the configuration described above, since the overlap of the second pass band and the inductive region of the series-arm resonator s11 is reduced, the impedance in the second pass band when the filters 10 and 20 are viewed from the common terminal 100 may be shifted from the inductive region toward the capacitive region. This makes it possible to position the impedance in the second pass band when the filters 10 and 20 are viewed from the common terminal 100 close to the impedance (reference impedance) in the second pass band optimized by the filter 20 alone. Thus, the insertion loss in the second pass band of the multiplexer 1 may be reduced.

For example, in the multiplexer 1, the resonant frequency frs11 of the series-arm resonator s11 is higher than the low frequency end of the first pass band.

With the configuration described above, the series-arm resonator s11 does not shift both of the resonant frequency frs11 and the anti-resonant frequency fas11 to a low frequency side by increasing the electrode finger pitch, but shifts only the anti-resonant frequency fas11 to a low frequency side by decreasing the resonance band width. Thus, the overlap of the second pass band and the inductive region of the series-arm resonator s11 may be reduced without increasing insertion loss of the filter 10.

For example, in the multiplexer 1, the series-arm resonator s11 includes the acoustic wave resonator 71 and the capacitor 91 coupled to the acoustic wave resonator 71 in parallel.

With the configuration described above, the anti-resonant frequency fas11 of the series-arm resonator s11 may be shifted to a lower frequency side than the anti-resonant frequency fa71 of the acoustic wave resonator 71, without shifting the resonant frequency frs11 of the series-arm resonator s11 from the resonant frequency fr71 of the acoustic wave resonator 71. Thus, the resonance band width of the series-arm resonator s11 may be made narrower relative to the resonance band width of the acoustic wave resonator 71.

For example, in the multiplexer 1, the acoustic wave resonator of the series-arm resonator s11 includes an IDT electrode, the IDT electrode includes a pair of comb-shaped electrodes each including a plurality of electrode fingers extending in a direction intersecting an acoustic wave propagation direction and disposed parallel to each other and a busbar electrode coupling one ends of the plurality of electrode fingers. When an electrode finger, among the plurality of electrode fingers, not coupled to any of the busbar electrodes of the pair of comb-shaped electrodes is defined as a floating withdrawal electrode, an electrode finger, among the plurality of electrode fingers, coupled to the same busbar electrode to which the electrode fingers on both sides of the electrode finger are coupled, is defined as a polarity-inverted withdrawal electrode, and an electrode finger, among the plurality of electrode fingers, having the maximum electrode finger width and having the electrode finger width of twice or more an average electrode finger width of the electrode fingers excluding the electrode finger is defined as a filled-in withdrawal electrode, the IDT electrode of the series-arm resonator s11 includes any of the floating withdrawal electrode, the polarity-inverted withdrawal electrode, and the filled-in withdrawal electrode.

With the configuration described above, the resonance band width of the series-arm resonator s11 becomes narrow, and the anti-resonant frequency fas11 may be made low.

For example, in the multiplexer 1, each of the plurality of acoustic wave resonators included in the filter 10 includes the piezoelectric substrate 50, the IDT electrode disposed on the piezoelectric substrate 50, and the first dielectric film disposed between the piezoelectric substrate 50 and the IDT electrode or on the IDT electrode, and the series-arm resonator s11 among the series-arm resonators s11 to s14 includes the thickest first dielectric film.

With the configuration described above, the resonance band width of the series-arm resonator s11 becomes narrow, and the anti-resonant frequency fas11 may be made low.

The multiplexer 1 according to the present example embodiment includes the filter 10 having the first pass band and the filter 20 having the second pass band on a higher frequency side than the first pass band, and the filters 10 and 20 are coupled to the common terminal 100. The filter 20 includes two or more series-arm resonators s21 to s25 each including an acoustic wave resonator and disposed in the series-arm path coupling the input end and the output end, and one or more parallel-arm resonators p21 to p24 each including an acoustic wave resonator and coupled between the series-arm path and the ground. The resonance band width of at least one of the series-arm resonators s21 to s24 is larger than the second pass band. The series-arm resonator s21 (second series-arm resonator) is coupled closest to the common terminal 100 among the series-arm resonators s21 to s25 and the parallel-arm resonators p21 to p24. The resonant frequency frs21 of the series-arm resonator s21 is higher than the high frequency end of the first pass band and is highest among the resonant frequencies positioned on a higher frequency side than the first pass band among the resonant frequencies frs21 to frs25 of the series-arm resonators s21 to s25.

With the configuration described above, since the capacitive region in which the capacitance of the series-arm resonator s21 is small overlaps with the first pass band of the filter 10, the impedance in the first pass band when the filters 10 and 20 are viewed from the common terminal 100 may be shifted from the capacitive region toward the inductive region. This makes it possible to position the impedance in the first pass band when the filters 10 and 20 are viewed from the common terminal 100 close to the impedance (reference impedance) in the first pass band optimized by the filter 10 alone. Thus, the insertion loss in the first pass band of the multiplexer 1 may be reduced.

For example, in the multiplexer 1, the parallel-arm resonator p21 (first parallel-arm resonator) is coupled to the series-arm resonator s21, and the resonance frequency frp21 of the parallel-arm resonator p21 is lower than the high frequency end of the first pass band and is highest among the resonant frequencies positioned on a lower frequency side than the second pass band among the resonant frequencies frp21 to frp24 of the parallel-arm resonators p21 to p24.

With the configuration described above, the shift amount of the impedance in the first pass band, when the filters 10 and 20 are viewed from the common terminal 100, from the impedance (reference impedance) in the first pass band optimized by the filter 10 alone may be made small. Thus, the insertion loss in the first pass band of the multiplexer 1 may further be reduced.

For example, in the multiplexer 1, the series-arm resonator s21 includes the second acoustic wave resonator and the second capacitance element coupled to the second acoustic wave resonator in parallel.

With the configuration described above, by adjusting the electrode finger pitch, the resonant frequency frs21 of the series-arm resonator s21 may be shifted to a higher frequency side than the resonant frequency of the second acoustic wave resonator.

For example, in the multiplexer 1, the IDT electrode of the series-arm resonator s21 includes any of the floating withdrawal electrode, the polarity-inverted withdrawal electrode, and the filled-in withdrawal electrode.

With the configuration described above, the resonance band width of the series-arm resonator s21 becomes narrow, and the resonant frequency frs21 may be made high.

For example, in the multiplexer 1, each of the plurality of acoustic wave resonators included in the filter 20 includes the piezoelectric substrate 50, the IDT electrode disposed on the piezoelectric substrate 50, and the second dielectric film disposed between the piezoelectric substrate 50 and the IDT electrode or on the IDT electrode, and the series-arm resonator s21 among the series-arm resonators s21 to s25 includes the thickest second dielectric film.

With the configuration above, the resonance band width of the series-arm resonator s21 becomes narrow, and the anti-resonant frequency fas21 may be made low.

The multiplexer 1 according to the present example embodiment includes the filter 10 having the first pass band and the filter 20 having the second pass band on a higher frequency side than the first pass band, and the filters 10 and 20 are coupled to the common terminal 100. The filter 10 includes the two or more series-arm resonators s11 to s14 each including an acoustic wave resonator and disposed in the series-arm path coupling the input end and the output end, and the one or more parallel-arm resonators p11 to p14 each including an acoustic wave resonator and coupled between the series-arm path and the ground. The filter 20 includes the two or more series-arm resonators s21 to s25 each including an acoustic wave resonator and disposed in the series-arm path coupling the input end and the output end, and the one or more parallel-arm resonators p21 to p24 each including an acoustic wave resonator and coupled between the series-arm path and the ground. Each of the acoustic wave resonators of the filters 10 and 20 includes the IDT electrode, and the electrode finger pitch of the IDT electrode of at least one of the series-arm resonators s11 to s14 is smaller than the electrode finger pitch of the IDT electrode of at least one of the parallel-arm resonators p21 to p24. The series-arm resonator s11 (first series-arm resonator) is coupled closest to the common terminal 100 among the series-arm resonators s11 to s14 and the parallel-arm resonators p11 to p14. The anti-resonant frequency fas11 of the series-arm resonator s11 is lower than the high frequency end of the second pass band and is lowest among the anti-resonant frequencies positioned on a higher frequency side than the first pass band among the anti-resonant frequencies fas11 to fas14 of the series-arm resonators s11 to s14.

With the configuration described above, since the overlap of the second pass band and the inductive region of the series-arm resonator s11 is reduced, the impedance in the second pass band when the filters 10 and 20 are viewed from the common terminal 100 may be shifted from the inductive region toward the capacitive region. This makes it possible to position the impedance in the second pass band when the filters 10 and 20 are viewed from the common terminal 100 close to the impedance (reference impedance) in the second pass band improved or optimized by the filter 20 alone. Thus, the insertion loss in the second pass band of the multiplexer 1 may be reduced.

The multiplexer 1 according to the present example embodiment includes the filter 10 having the first pass band and the filter 20 having the second pass band on a higher frequency side than the first pass band, and the filters 10 and 20 are coupled to the common terminal 100. The filter 10 includes the two or more series-arm resonators s11 to s14 each including an acoustic wave resonator and disposed in the series-arm path coupling the input end and the output end, and the one or more parallel-arm resonators p11 to p14 each including an acoustic wave resonator and coupled between the series-arm path and the ground. The filter 20 includes the two or more series-arm resonators s21 to s25 each including an acoustic wave resonator and disposed in the series-arm path coupling the input end and the output end, and the one or more parallel-arm resonators p21 to p24 each including an acoustic wave resonator and coupled between the series-arm path and the ground. Each of the acoustic wave resonators of the filters 10 and 20 includes the IDT electrode, and the electrode finger pitch of the IDT electrode of at least one of the series-arm resonators s11 to s14 is smaller than the electrode finger pitch of the IDT electrode of at least one of the parallel-arm resonators p21 to p24. The series-arm resonator s21 (second series-arm resonator) is coupled closest to the common terminal 100 among the series-arm resonators s21 to s25 and the parallel-arm resonators p21 to p24. The electrode finger pitch of the IDT electrode of the series-arm resonator s21 is the smallest among the electrode finger pitches of the IDT electrodes of the series-arm resonators s21 to s25.

With the configuration described above, since the capacitive region in which the capacitance of the series-arm resonator s21 is small overlaps with the first pass band of the filter 10, the impedance in the first pass band when the filters 10 and 20 are viewed from the common terminal 100 may be shifted from the capacitive region toward the inductive region. This makes it possible to position the impedance in the first pass band when the filters 10 and 20 are viewed from the common terminal 100 close to the impedance (reference impedance) in the first pass band improved or optimized by the filter 10 alone. Thus, the insertion loss in the first pass band of the multiplexer 1 may be reduced.

### Other Example Embodiments

Although multiplexers according to the present invention have been described with reference to the example embodiments, the present invention is not limited to the example embodiments. The present invention includes modified examples obtained by making various modifications to the example embodiments that can be conceived by those skilled in the art without departing from the scope and spirit of the present invention, and various devices incorporating the multiplexers according to example embodiments of the present invention.

Further, for example, in the multiplexers according to the example embodiments, a matching element such as, for example, an inductor or a capacitor and a switch circuit may be coupled between the various elements.

The resonant frequency and the anti-resonant frequency described in the example embodiments are determined by, for example, measuring a reflection characteristic with an RF probe in contact to two input/output electrodes of the acoustic wave resonator.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multiplexer, comprising:
a first filter with a first pass band; and
a second filter with a second pass band on a higher frequency side than the first pass band; wherein
the first filter and the second filter are coupled to a common terminal;
the first filter includes two or more series-arm resonators each including an acoustic wave resonator and provided in a series-arm path coupling an input end and an output end, and one or more parallel-arm resonators each including an acoustic wave resonator and provided between the series-arm path and a ground;
a resonance band width of at least one of the two or more series-arm resonators included in the first filter is wider than the first pass band;
a first series-arm resonator among the two or more series-arm resonators included in the first filter is coupled closest to the common terminal among the two or more series-arm resonators and the one or more parallel-arm resonators included in the first filter; and
an anti-resonant frequency of the first series-arm resonator is lower than a high frequency end of the second pass band, and is lowest among anti-resonant frequencies positioned on the higher frequency side than the first pass band among anti-resonant frequencies of the two or more series-arm resonators included in the first filter.

2. The multiplexer according to claim 1, wherein
the second filter includes two or more series-arm resonators each including an acoustic wave resonator and provided in a series-arm path coupling an input end and an output end, and one or more parallel-arm resonators each including an acoustic wave resonator and coupled between the series-arm path and the ground;
a resonance band width of at least one of the two or more series-arm resonators included in the second filter is wider than the second pass band;
a second series-arm resonator among the two or more series-arm resonators included in the second filter is coupled closest to the common terminal among the two or more series-arm resonators and the one or more parallel-arm resonators included in the second filter; and
a resonant frequency of the second series-arm resonator is higher than a high frequency end of the first pass band, and is highest among resonant frequencies positioned on the higher frequency side than the first pass band among resonant frequencies of the two or more series-arm resonators included in the second filter.

3. The multiplexer according to claim 1, wherein a resonant frequency of the first series-arm resonator is higher than a low frequency end of the first pass band.

4. The multiplexer according to claim 1, wherein
the first series-arm resonator includes:
a first acoustic wave resonator; and
a first capacitor portion coupled to the first acoustic wave resonator in parallel.

5. The multiplexer according to claim 1, wherein
the acoustic wave resonator of the first series-arm resonator includes an IDT electrode;
the IDT electrode includes a pair of comb-shaped electrodes each including a plurality of electrode fingers extending in a direction intersecting an acoustic wave propagation direction and being parallel to each other, and a busbar electrode coupling one ends of the plurality of electrode fingers; and
when an electrode finger, among the plurality of electrode fingers, not coupled to any of the busbar electrodes of the pair of comb-shaped electrodes is a floating withdrawal electrode, an electrode finger, among the plurality of electrode fingers, coupled to a same busbar electrode to which the electrode fingers on both sides of the electrode finger are coupled is a polarity-inverted withdrawal electrode, and an electrode finger, among the plurality of electrode fingers, having a maximum electrode finger width equal to about twice or more an average electrode finger width of the electrode fingers excluding the electrode finger is a filled-in withdrawal electrode, the IDT electrode of the first series-arm resonator includes any of the floating withdrawal electrode, the polarity-inverted withdrawal electrode, or the filled-in withdrawal electrode.

6. The multiplexer according to claim 5, wherein each of the plurality of electrode fingers and the busbar electrode has a multilayer structure including an adhesion layer and a main electrode layer.

7. The multiplexer according to claim 1, wherein
each of the acoustic wave resonators included in the first filter includes:
a piezoelectric substrate:
an IDT electrode on the piezoelectric substrate;
a first dielectric film between the piezoelectric substrate and the IDT electrode or on the IDT electrode; and
the first dielectric film of the first series-arm resonator is thickest among the two or more series-arm resonators included in the first filter.

8. A multiplexer, comprising:
a first filter with a first pass band; and
a second filter with a second pass band on a higher frequency side than the first pass band; wherein
the first filter and the second filter are coupled to a common terminal;
the second filter includes two or more series-arm resonators each including an acoustic wave resonator and provided in a series-arm path coupling an input end and an output end, and one or more parallel-arm resonators each including an acoustic wave resonator and coupled between the series-arm path and a ground;
a resonance band width of at least one of the two or more series-arm resonators included in the second filter is wider than the second pass band;
a second series-arm resonator among the two or more series-arm resonators included in the second filter is coupled closest to the common terminal among the two or more series-arm resonators and the one or more parallel-arm resonators included in the second filter; and
a resonant frequency of the second series-arm resonator is higher than a high frequency end of the first pass band, and is highest among resonant frequencies positioned on the higher frequency side than the first pass band among resonant frequencies of the two or more series-arm resonators included in the second filter.

9. The multiplexer according to claim 8, wherein
the second filter includes the two or more series-arm resonators and two or more parallel-arm resonators each including the acoustic wave resonator and coupled between the series-arm path and the ground;
a first parallel-arm resonator among the two or more parallel-arm resonators included in the second filter is coupled to the second series-arm resonator; and
a resonant frequency of the first parallel-arm resonator is lower than the high frequency end of the first pass band, and is highest among resonant frequencies positioned on a lower frequency side than the second pass band among resonant frequencies of the two or more parallel-arm resonators included in the second filter.

10. The multiplexer according to claim 8, wherein
the second series-arm resonator includes:
a second acoustic wave resonator; and
a second capacitor portion coupled to the second acoustic wave resonator in parallel.

11. The multiplexer according to claim 8, wherein
the acoustic wave resonator of the second series-arm resonator includes an IDT electrode;
the IDT electrode includes a pair of comb-shaped electrodes each including a plurality of electrode fingers extending in a direction intersecting an acoustic wave propagation direction and disposed parallel to each other, and a busbar electrode coupling one ends of the electrode fingers of the plurality of electrode fingers; and
when an electrode finger, among the plurality of electrode fingers, not coupled to any of the busbar electrodes of the pair of comb-shaped electrodes is a floating withdrawal electrode, an electrode finger, among the plurality of electrode fingers, coupled to a same busbar electrode to which the electrode fingers on both sides of the electrode finger are coupled is a polarity-inverted withdrawal electrode, and an electrode finger, among the plurality of electrode fingers, having a maximum electrode finger width and having the electrode finger width of twice or more an average electrode finger width of the electrode fingers excluding the electrode finger is a filled-in withdrawal electrode, the IDT electrode of the second series-arm resonator includes any of the floating withdrawal electrode, the polarity-inverted withdrawal electrode, or the filled-in withdrawal electrode.

12. The multiplexer according to claim 11, wherein each of the plurality of electrode fingers and the busbar electrode has a multilayer structure including an adhesion layer and a main electrode layer.

13. The multiplexer according to claim 8, wherein
each of the acoustic wave resonators included in the second filter includes:
a piezoelectric substrate;
an IDT electrode on the piezoelectric substrate;
a second dielectric film between the piezoelectric substrate and the IDT electrode or on the IDT electrode; and
the second dielectric film of the second series-arm resonator is thickest among the two or more series-arm resonators included in the second filter.

14. A multiplexer, comprising:
a first filter with a first pass band; and
a second filter with a second pass band on a higher frequency side than the first pass band; wherein
the first filter and the second filter are coupled to a common terminal;
the first filter includes two or more series-arm resonators each including an acoustic wave resonator and provided in a series-arm path coupling an input end and an output end, and one or more parallel-arm resonators each including an acoustic wave resonator and coupled between the series-arm path and a ground;
the second filter includes two or more series-arm resonators each including an acoustic wave resonator and provided in a series-arm path coupling an input end and an output end, and one or more parallel-arm resonators each including an acoustic wave resonator and coupled between the series-arm path and the ground;
each of the acoustic wave resonators of the first filter and the second filter includes an interdigital transducer (IDT) electrode;
an electrode finger pitch of the IDT electrode of at least one of the two or more series-arm resonators included in the first filter is smaller than an electrode finger pitch of the IDT electrode of at least one of the one or more parallel-arm resonators included in the second filter;
a first series-arm resonator among the two or more series-arm resonators included in the first filter is coupled closest to the common terminal among the two or more series-arm resonators and the one or more parallel-arm resonators included in the first filter; and
an anti-resonant frequency of the first series-arm resonator is lower than a high frequency end of the second pass band and is lowest among anti-resonant frequencies positioned on the higher frequency side than the first pass band among anti-resonant frequencies of the two or more series-arm resonators included in the first filter.

15. The multiplexer according to claim 14, wherein
an electrode finger pitch of the IDT electrode of at least one of the two or more series-arm resonators included in the second filter is smaller than the electrode finger pitch of the IDT electrode of at least one of the one or more parallel-arm resonators included in the second filter;
a second series-arm resonator among the two or more series-arm resonators included in the second filter is coupled closest to the common terminal among the two or more series-arm resonators and the one or more parallel-arm resonators included in the second filter; and
an electrode finger pitch of the IDT electrode of the second series-arm resonator is smallest among electrode finger pitches of the IDT electrodes of the two or more series-arm resonators included in the second filter.

16. The multiplexer according to claim 14, wherein each of the plurality of electrode fingers and the busbar electrode has a multilayer structure including an adhesion layer and a main electrode layer.

17. A multiplexer, comprising:
a first filter with a first pass band; and
a second filter with a second pass band on a higher frequency side than the first pass band; wherein
the first filter and the second filter are coupled to a common terminal;
the first filter includes two or more series-arm resonators each including an acoustic wave resonator and provided in a series-arm path coupling an input end and an output end, and one or more parallel-arm resonators each including an acoustic wave resonator and coupled between the series-arm path and a ground;
the second filter includes two or more series-arm resonators each including an acoustic wave resonator and provided in a series-arm path coupling an input end and an output end, and one or more parallel-arm resonators each including an acoustic wave resonator and coupled between the series-arm path and the ground;
each of the acoustic wave resonators of the first filter and the second filter includes an IDT electrode;
an electrode finger pitch of the IDT electrode of at least one of the two or more series-arm resonators included in the second filter is smaller than an electrode finger pitch of the IDT electrode of at least one of the one or more parallel-arm resonators included in the second filter;
a second series-arm resonator among the two or more series-arm resonators included in the second filter is coupled closest to the common terminal among the two or more series-arm resonators and the one or more parallel-arm resonators included in the second filter; and
an electrode finger pitch of the IDT electrode of the second series-arm resonator is smallest among electrode finger pitches of the IDT electrodes of the two or more series-arm resonators included in the second filter.

18. The multiplexer according to claim 17, wherein each of the plurality of electrode fingers and the busbar electrode has a multilayer structure including an adhesion layer and a main electrode layer.
